(19) United States
(12) Patent Application Publication
(10) Pub. No.: US 2023/0253529 A1
(43) Pub. Date: Aug. 10, 2023

(54) DISPLAY DEVICE AND METHOD OF MANUFACTURING THE SAME

(71) Applicant: Samsung Display Co., LTD., Yongin-si (KR)

(72) Inventor: Kyong Sub KIM, Yongin-si (KR)

(21) Appl. No.: 17/971,304

(22) Filed: Oct. 21, 2022

(30) Foreign Application Priority Data
Feb. 9, 2022 (KR) 10-2022-0017127

(51) Int. Cl. H01L 33/38; H01L 33/00; H01L 33/62; H01L 33/50

(52) U.S. Cl. CPC H01L 33/387; H01L 33/005; H01L 33/62; H01L 33/50; H01L 2933/0016; H01L 2933/0066

(57) ABSTRACT

According to a method of manufacturing a display device, an insulating layer is formed on a panel including a first electrode and a second electrode provided in each of emission areas and spaced apart from each other. A first voltage is applied to at least one of the first and second electrodes. Charged light emitting elements are attached to the emission areas using static electricity between the light emitting elements and the insulating layer.

### CROSS-REFERENCE TO RELATED APPLICATION

The application claims priority to and the benefit of Korean Patent Application No. 10-2022-0017127, filed Feb. 9, 2022, the entire content of which is hereby incorporated by reference.

### BACKGROUND

### 1, Field

One or more embodiments of the present disclosure relate to a display device and a method of manufacturing the same.

### 2. Description of the Related Art

As interest in information display increases and demand for use of portable information media increases, development of display devices and commercialization thereof are being focused on.

### SUMMARY

One or more embodiments of the present disclosure are directed toward a display device capable of reducing a deviation in luminance and a method of manufacturing the same.

A method of manufacturing a display device according to embodiments of the present disclosure may include forming an insulating layer on a panel including a first electrode and a second electrode provided in each of emission areas and spaced apart from each other; applying a first voltage to at least one of the first electrode and the second electrode; and attaching charged light emitting elements to the emission areas utilizing static electricity between the light emitting elements and the insulating layer.

Each of the light emitting elements may have a diameter and/or length in a range of a nano-meter scale to a micro-meter scale.

Each of the light emitting elements may include: a first semiconductor layer; a second semiconductor layer; an active layer between the first semiconductor layer and the second semiconductor layer; an insulating film surrounding (e.g., around) an outer peripheral surface of the active layer; and an insulator surrounding (e.g., around) the first semiconductor layer, the second semiconductor layer, and the insulating film.

The insulator may include at least one of carbon or an acrylic resin.

The insulator may cover the first and second semiconductor layers exposed by the insulating film.

The attaching the charged light emitting elements to the emission areas may include: charging the light emitting elements and attaching the charged light emitting elements to an outer peripheral surface of a transfer roller; and transferring the light emitting elements to the emission areas using (e.g., from) the transfer roller.

The applying the first voltage to at least one of the first electrode and the second electrode may include applying the first voltage to each of the first and second electrodes.

The first electrode may be configured to be separated for each of the emission areas, and may be connected to a first alignment power source line through a first switching element, and the second electrode may be configured to be separated for each of the emission areas, and may be connected to a second alignment power source line through a second switching element.

The applying the first voltage to at least one of the first electrode and the second electrode may include: connecting the first and second electrodes to the first and second alignment power source lines by turning on the first and second switching elements; and turning off the first and second switching elements before attaching the light emitting elements to the emission areas.

The method of manufacturing a display device may further include: supplying a solvent to the emission areas; and aligning the light emitting elements between the first and second electrodes in each of the emission areas by applying a first alignment voltage and a second alignment voltage to the first electrode and the second electrode, respectively, and one of the first and second alignment voltages may be an AC voltage, and another of the first and second alignment voltages may be a ground voltage.

The supplying the solvent to the emission areas may include supplying the solvent to each of the emission areas using (e.g., through) an inkjet method.

The method of manufacturing a display device may further include forming an insulating pattern on the light emitting elements between the first and second electrodes.

A method of manufacturing a display device according to embodiments of the present disclosure may include: forming an insulating layer on a panel including emission areas and a non-emission area; charging the insulating layer by applying a first power source to the insulating layer; partially removing static electricity from the insulating layer in the non-emission area by irradiating light to the non-emission area; and attaching charged light emitting elements to the emission areas using static electricity between the light emitting elements and the insulating layer.

The attaching the charged light emitting elements to the emission areas may include: charging the light emitting elements and attaching the charged light emitting elements to an outer peripheral surface of a transfer roller; and attaching the light emitting elements to the emission areas using (e.g., from) the transfer roller.

The method of manufacturing a display device may further include: supplying a solvent to the emission areas; and aligning the light emitting elements between first and second electrodes in each of the emission areas by applying a first alignment voltage and a second alignment voltage to the first electrode and the second electrode provided under the insulating layer, respectively, and one of the first and second alignment voltages may be an AC voltage, and another of the first and second alignment voltages may be a ground voltage.

In order to achieve the object of the present disclosure, a display device according to embodiments of the present disclosure may include: a first electrode and a second electrode provided in each of emission areas of a substrate and spaced apart from each other; an insulating layer provided on the substrate to cover the first and second electrodes; a light emitting element provided on the insulating layer and aligned between the first and second electrodes; a first contact electrode provided on the first electrode and in contact with a first end of the light emitting element; and a second contact electrode provided on the second electrode and in contact with a second end of the light emitting element. The light emitting element may include: a first semiconductor layer; a second semiconductor layer; an active layer between the first semiconductor layer and the second semiconductor layer; an insulating film surrounding (e.g., around) an outer peripheral surface of the active layer; and an insulator surrounding (e.g., around) the first semiconductor layer, the second semiconductor layer, and the insulating film.

The insulator may include at least one of carbon and an acrylic resin.

The light emitting element may have a diameter and/or length in a range of a nano-meter scale to a micro-meter scale.

The first electrode may be configured to be separated for each of the emission areas, and may be connected to a first alignment power source line through a first switching element, and the second electrode may be configured to be separated for each of the emission areas, and may be connected to a second alignment power source line through a second switching element.

The display device may further include color conversion particles provided on the light emitting element and configured to convert a wavelength of light emitted from the light emitting element.

### BRIEF DESCRIPTION OF THE DRAWINGS

The accompanying drawings, which are included to provide a further understanding of the present disclosure, and are incorporated in and constitute a part of this specification, illustrate embodiments of the present disclosure, and, together with the description, serve to explain principles of the present disclosure.

FIGS. 1 and 2 are respectively a perspective view and a cross-sectional view illustrating a light emitting element according to one or more embodiments.

FIG. 3 is a plan view illustrating a display device according to one or more embodiments.

FIGS. 4A, 4B, and 4C are circuit diagrams illustrating one or more embodiments of a pixel included in the display device of FIG. 3.

FIG. 5 is a cross-sectional view illustrating one or more embodiments of the pixel included in the display device of FIG. 3.

FIGS. 6A and 6B are cross-sectional views illustrating one or more embodiments of a pixel unit included in the display device of FIG. 3.

FIGS. 7A, 7B, 7C, and 7D are cross-sectional views schematically illustrating a method of manufacturing a display device according to one or more embodiments.

FIGS. 8A-8C are plan views schematically illustrating the method of manufacturing a display device according to one or more embodiments.

FIGS. 9A and 9B are cross-sectional views schematically illustrating a method of manufacturing a display device according to one or more embodiments.

### DETAILED DESCRIPTION

As the present disclosure allows for various changes and numerous embodiments, particular embodiments will be illustrated in the drawings and described in more detail in the written description. However, this is not intended to limit the present disclosure to particular modes of practice, and it is to be appreciated that all changes, equivalents, and substitutes that do not depart from the spirit and technical scope of the present disclosure are encompassed in the present disclosure.

It will be understood that, although the terms “first”, “second”, etc. may be used herein to describe various elements, these elements should not be limited by these terms. These terms are only used to distinguish one element from another element. For instance, a first element discussed below could be termed a second element without departing from the scope of the present disclosure. Similarly, the second element could also be termed the first element. In the disclosure, the singular expressions are intended to include the plural expressions, unless the context clearly indicates otherwise.

It will be further understood that the terms “comprise”, “include”, “have”, etc. used in the disclosure, specify the presence of stated features, integers, steps, operations, elements, components, and/or combinations of them but do not preclude the presence or addition of one or more other features, integers, steps, operations, elements, components, and/or combinations thereof. In addition, when a first part such as a layer, film, region, plate, etc. is “on” a second part, this may include the case where the first part is “directly on” the second part (e.g., without any intervening elements therebetween), as well as the case where a third part is interposed between them. Furthermore, in the disclosure, when a first part such as a layer, film, region, plate, etc. is formed on a second part, a direction in which the first part is formed is not limited to an upper direction of the second part, but may include a side or a lower direction of the second part. Also, when a first part such as a layer, film, region, plate, etc. is “under” a second part, this may include not only the case where the first part is “directly under” the second part (e.g., without any intervening elements therebetween), but also the case where a third part is interposed therebetween.

Advantages and features of the present disclosure, and methods for accomplishing the same will be more clearly understood from embodiments described below with reference to the accompanying drawings. However, the present disclosure is not limited to the following embodiments but may be implemented in various different forms. In the description below, when a first part is connected to a second part, this may include the case where the first part is directly connected to the second part as well as the case where the first part is electrically connected to the second part, with a third part connected between them.

As used herein, the singular forms “a,” “an,” and “the” are intended to include the plural forms as well, unless the context clearly indicates otherwise.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list. For example, “at least one selected from a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items. Further, the use of “may” when describing embodiments of the present disclosure refers to “one or more embodiments of the present disclosure”.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Hereinafter, a display device according to one or more embodiments of the present disclosure will be described with reference to the drawings related to the embodiments of the present disclosure.

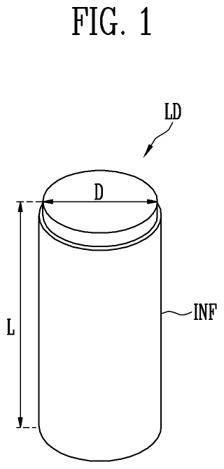

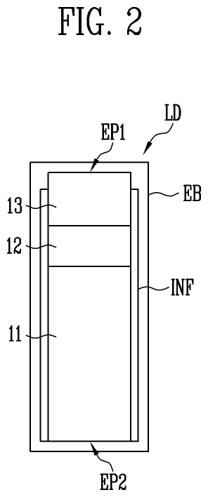

FIGS. 1 and 2 are a perspective view and a cross-sectional view illustrating a light emitting element according to one or more embodiments. FIGS. 1 and 2 show a columnar light emitting element LD, but the type (or kind) and/or shape of the light emitting element LD is not limited thereto.

Referring to FIGS. 1 and 2, the light emitting element LD may include a first semiconductor layer 11, a second semiconductor layer 13, and an active layer 12 interposed between the first and second semiconductor layers 11 and 13. For example, when a direction in which the light emitting element LD extends is referred to as a length L direction, the light emitting element LD may include the first semiconductor layer 11, the active layer 12, and the second semiconductor layer 13 sequentially stacked along the length L direction.

The light emitting element LD may be provided in a columnar shape extending in one direction. The light emitting element LD may have a first end EP1 and a second end EP2. One of the first and second semiconductor layers 11 and 13 may be provided at the first end EP1 of the light emitting element LD. The other one of the first and second semiconductor layers 11 and 13 may be provided at the second end EP2 of the light emitting element LD.

According to one or more embodiments, the light emitting element LD may be a light emitting element manufactured in a columnar shape through an etching method and/or the like. In this specification, the columnar shape may generally refer to a rod-like shape or a bar-like shape that is long (e.g., has an aspect ratio greater than 1) in the length L direction, such as a cylinder or a polygonal column, and the shape of the cross-section thereof is not particularly limited. For example, a length L of the light emitting element LD may be greater than a diameter D (or a width of a cross-section) thereof.

The light emitting element LD may have a size as small as a nano-meter scale to a micro-meter scale. For example, the light emitting element LD may have the diameter D (or width) and/or the length L ranging from a nano-meter scale to a micro-meter scale. However, the size of the light emitting element LD is not limited thereto. The size of the light emitting element LD may be variously suitably changed according to design conditions of various devices using a light emitting device using the light emitting element LD as a light source, for example, a display device.

The first semiconductor layer 11 may be a semiconductor layer of a first conductivity type. For example, the first semiconductor layer 11 may include an N-type semiconductor layer. For example, the first semiconductor layer 11 may include an N-type semiconductor layer including any one semiconductor material of InAlGaN, GaN, AlGaN, InGaN, AlN, or InN, and doped with a first conductivity type dopant (e.g., an N-type dopant) such as Si, Ge, Sn, and/or the like. However, the material constituting the first semiconductor layer 11 is not limited thereto, and one or more other suitable materials may be used to form the first semiconductor layer 11.

The active layer 12 may be provided on the first semiconductor layer 11 and may have a single-quantum well or multi-quantum well structure. A position of the active layer 12 may be variously suitably changed according to the type (or kind) of the light emitting element LD.

A clad layer doped with a conductive dopant may be formed on the upper and/or lower portions of the active layer 12. For example, the clad layer may be formed of AlGaN and/or InAlGaN. According to one or more embodiments, a material such as AlGaN and/or InAlGaN may be used to form the active layer 12, and one or more other suitable materials may be used to form the active layer 12.

The second semiconductor layer 13 may be provided on the active layer 12 and may include a semiconductor layer of a different type from that of the first semiconductor layer 11. For example, the second semiconductor layer 13 may include a P-type semiconductor layer. For example, the second semiconductor layer 13 may include a P-type semiconductor layer including at least one semiconductor material of InAlGaN, GaN, AlGaN, InGaN, AlN, or InN, and doped with a second conductivity type dopant (e.g., a P-type dopant) such as Mg and/or the like. However, the material constituting the second semiconductor layer 13 is not limited thereto, and one or more other suitable materials may be used to form the second semiconductor layer 13.

When a voltage equal to or greater than a threshold voltage is applied to both ends of the light emitting element LD, the light emitting element LD may emit light while electron-hole pairs are combined in the active layer 12. By controlling the light emitted by the light emitting element LD using this principle, the light emitting element LD can be used as a light source for various suitable light emitting devices including pixels of a display device.

The light emitting element LD may further include a first insulating film INF (or an insulating film) provided on a surface thereof. The first insulating film INF may be formed on a surface of the light emitting element LD to surround at least an outer peripheral surface of the active layer 12. In some embodiments, the first insulating film INF may further surround one region of the first and/or the second semiconductor layers 11 and 13.

According to one or more embodiments, the first insulating film INF may expose both ends of the light emitting element LD having different polarities. For example, the first insulating film INF may expose one end of each of the first and second semiconductor layers 11 and 13 respectively positioned at the first and second ends EP1 and EP2 of the light emitting element LD. In other embodiments, the first insulating film INF may expose side portions of the first and second semiconductor layers 11 and 13 respectively adjacent to the first and second ends EP1 and EP2 of the light emitting element LD having different polarities.

According to one or more embodiments, the first insulating film INF may be formed of a single layer or a multilayer (for example, a double layer formed of aluminum oxide (AlOx) and silicon oxide (SiOx)) including at least one insulating material of silicon oxide (SiOx), silicon nitride (SiNx), silicon oxynitride (SiOxNy), aluminum oxide (AlOx), or titanium oxide (TiOx), but the present disclosure is not limited thereto. In some embodiments, the first insulating film INF may not be provided.

When the first insulating film INF is provided to cover the surface of the light emitting element LD, for example, the outer peripheral surface of the active layer 12, it is possible to prevent or reduce the risk of a short-circuit of the active layer 12 with a first pixel electrode or a second pixel electrode, which will be described in more detail herein below. Accordingly, electrical stability of the light emitting element LD can be secured.

In addition, when the first insulating film INF is provided on the surface of the light emitting element LD, surface defects of the light emitting element LD may be minimized or reduced, so that lifespan and efficiency can be improved. In addition, even when a plurality of light emitting elements LD are provided adjacent to each other, the risk of an unwanted (e.g., undesirable or unsuitable) short circuit between the light emitting elements LD can be prevented or reduced.

In one or more embodiments, the light emitting element LD may further include additional components, in addition to the first semiconductor layer 11, the active layer 12, the second semiconductor layer 13, and/or the first insulating film INF surrounding them. For example, the light emitting element LD may further include one or more phosphor layers, active layers, semiconductor layers, and/or electrode layers provided on one end of the first semiconductor layer 11, the active layer 12, and/or the second semiconductor layer 13. For example, a contact electrode layer may be provided at the first and second ends EP1 and EP2 of the light emitting element LD, respectively. Although the columnar light emitting element LD is shown in FIGS. 1 and 2 as an example, the type (or kind), structure, and/or shape of the light emitting element LD may be variously suitably changed. For example, the light emitting element LD maybe formed in a core-shell structure having a polygonal pyramid shape.

In one or more embodiments, the light emitting element LD may further include a second insulating film EB (or insulator, a non-conductor or a first non-conductor) provided on the surface thereof. As shown in FIG. 2, the second insulating film EB may surround the first and second semiconductor layers 11 and 13, the active layer 12, and the first insulating film INF.

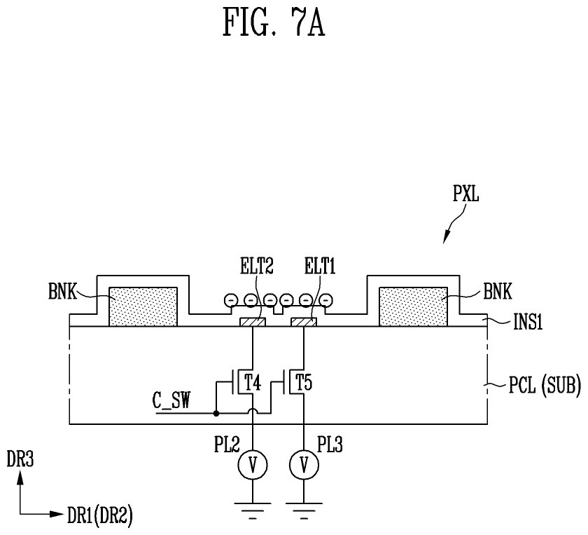

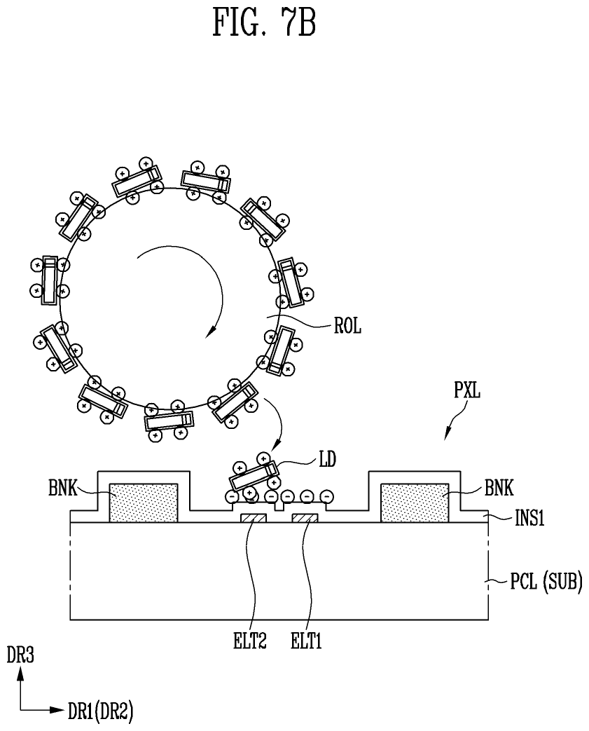

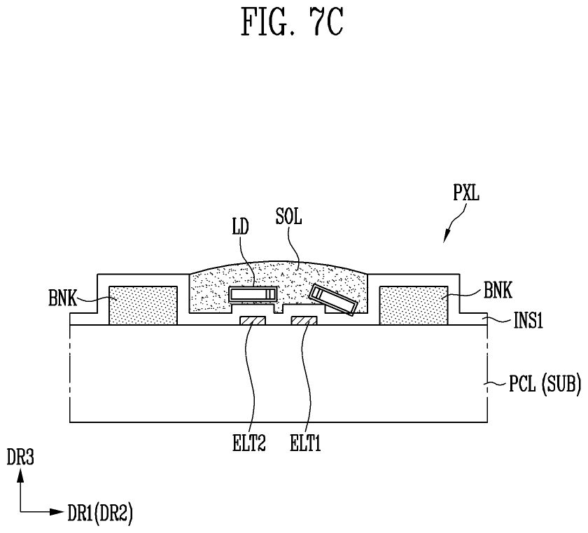

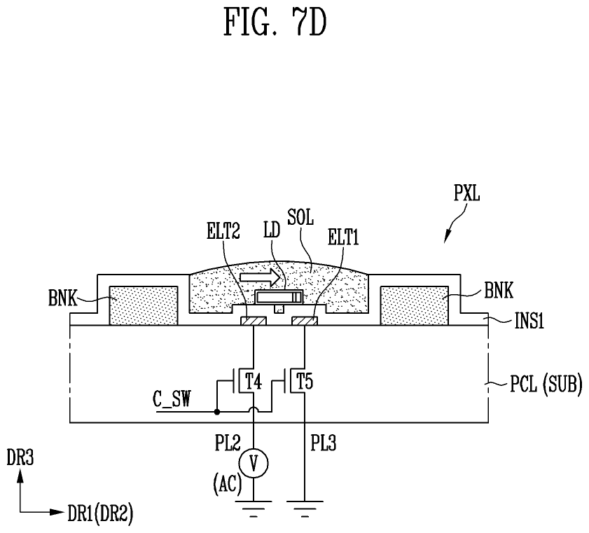

As will be described in more detail herein below with reference to FIG. 7B, the second insulating film EB may be charged (for example, may be a charged body) in a process of manufacturing a display device, and the light emitting element LD may be supplied to a display panel using an electrostatic force between the charged second insulating film EB and the display panel (or a substrate). For example, in the process of manufacturing the display device, the second insulating film EB of the light emitting element LD may be charged with a positive polarity, and the display panel (or the substrate) may be charged with a negative polarity. When the charged light emitting element LD approaches the display panel, the charged light emitting element LD may be transcribed (e.g., provided or attached) onto the display panel.

The second insulating film EB may be provided (for example, coated) on an entire surface of the light emitting element LD so that the light emitting element LD is uniformly (or substantially uniformly) charged as a whole, for example, so that electrostatic force (or electrostatic attraction) is uniformly applied (or substantially uniformly) to the light emitting element LD.

In one or more embodiments, the second insulating film EB may include carbon, an acrylate resin, and/or a polymer. The second insulating film EB may be charged with a positive polarity, but the present disclosure is not limited thereto.

A light emitting device including the above-described light emitting element LD may be used in one or more suitable types (or kinds) of devices requiring a light source, such as a display device. For example, a plurality of light emitting elements LD may be provided in each pixel of the display panel, and the light emitting elements LD may be used as light sources of each pixel. However, applications of the light emitting element LD are not limited to the above-described examples. For example, the light emitting element LD may be used in other types (or kinds) of devices requiring a light source, such as a lighting device.

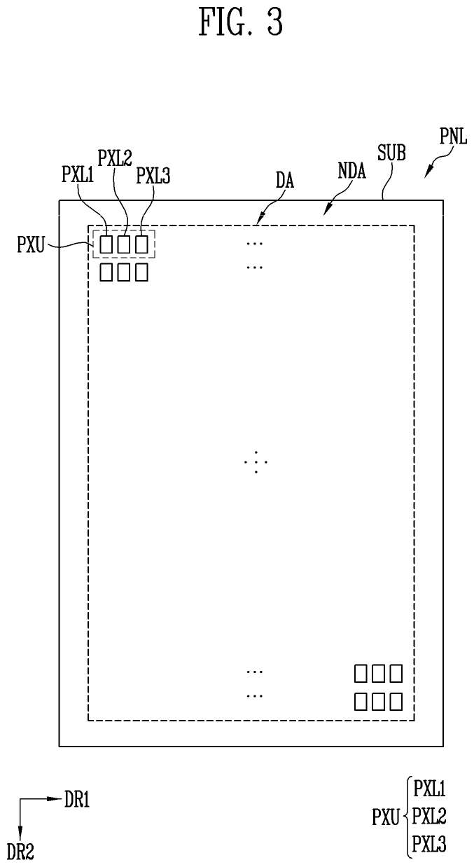

FIG. 3 is a plan view illustrating a display device according to embodiments. FIG. 3 shows a display device, for example, a display panel PNL provided in the display device, as an example of an electronic device in which the light emitting element LD described in the embodiments of FIGS. 1 and 2 can be used as a light source.

Each pixel unit PXU of the display panel PNL and each pixel constituting the same may include at least one light emitting element LD. For convenience, FIG. 3 schematically shows a structure of the display panel PNL with a display area DA at the center. However, according to one or more embodiments, at least one driving circuit unit (for example, at least one of a scan driver and a data driver), wirings, and/or pads may be further provided on the display panel PNL.

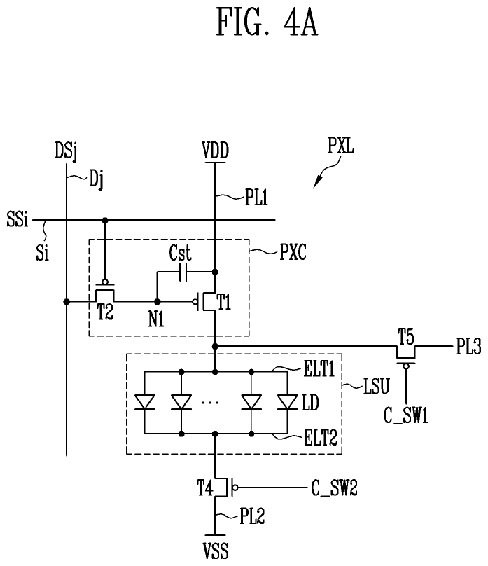

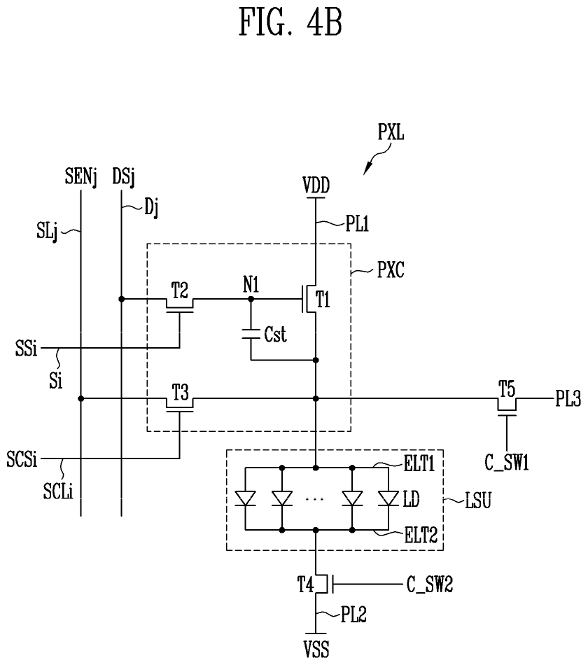

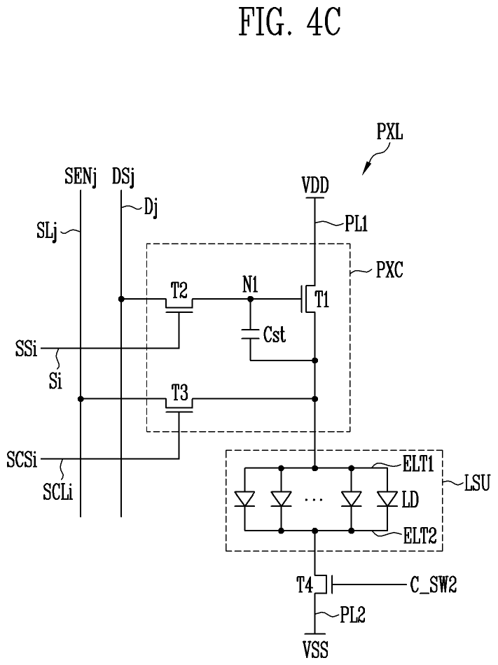

Referring to FIG. 3, the display panel PNL may include a substrate SUB and a pixel unit PXU provided on the substrate SUB. The pixel unit PXU may include first pixels PXL1, second pixels PXL2, and/or third pixels PXL3. Hereinafter, when at least one pixel among the first pixels PXL1, the second pixels PXL2, and the third pixels PXL3 is arbitrarily referred to, or when two or more pixels are generically referred to, they will be referred to as “pixel PXL (refer to FIGS. 4A to 4C)” or “pixels PXL”.

The substrate SUB may constitute a base member of the display panel PNL, and may be a rigid or flexible substrate or film. For example, the substrate SUB may be a rigid substrate made of glass or tempered glass, a flexible substrate (or thin film) made of plastic or metal, or at least one insulating layer. The material and/or properties of the substrate SUB are not particularly limited.

In one or more embodiments, the substrate SUB may be substantially transparent. Here, the expression “substantially transparent” may mean that light can be transmitted with a set or predetermined transmittance (for example, 80%) or more. In one or more other embodiments, the substrate SUB may be translucent or opaque. The substrate SUB may include a reflective material according to one or more embodiments.

The display panel PNL and the substrate SUB for forming the same may include a display area DA for displaying an image and a non-display area NDA excluding the display area DA.

Pixels PXL may be provided in the display area DA. One or more wirings, pads, and/or built-in circuit units connected to the pixels PXL of the display area NDA may be provided in the non-display area NDA. The pixels PXL may be regularly arranged according to a stripe or pentile (PENTILE®) arrangement structure (PENTILE® is a registered trademark owned by Samsung Display Co., Ltd.). However, an arrangement structure of the pixels PXL is not limited thereto, and the pixels PXL may be arranged in the display area DA in one or more suitable structures and/or methods.

According to one or more embodiments, two or more types (or kinds) of pixels PXL emitting (e.g., configured to emit) light of different colors may be provided in the display area DA. For example, first pixels PXL1 emitting light of a first color, second pixels PXL2 emitting light of a second color, and third pixels PXL3 emitting light of a third color may be arranged in the display area DA. For example, the first to third pixels PXL1, PXL2, and PXL3 may be sequentially provided repeatedly along a first direction DR1 and may be repeatedly provided with each other along a second direction DR2. First to third pixels PXL1, PXL2, and PXL3 provided adjacent to each other may constitute one pixel unit PXU capable of emitting light of various colors. For example, each of the first to third pixels PXL1, PXL2, and PXL3 may be a pixel emitting light of a set or predetermined color. According to one or more embodiments, the first pixel PXL1 may be a red pixel emitting red light, the second pixel PXL2 may be a green pixel emitting green light, and the third pixel PXL3 may be a blue pixel emitting blue light, but the present disclosure is not limited thereto.

In one or more embodiments, the first pixel PXL1, the second pixel PXL2, and the third pixel PXL3 may include a light emitting element of the first color, a light emitting element of the second color, and a light emitting element of the third color as light sources, and may emit light of the first color, the second color, and the third color, respectively. In one or more other embodiments, the first pixel PXL1, the second pixel PXL2, and the third pixel PXL3 may include light emitting elements emitting light of the same color, and may include color conversion layers and/or color filters of different colors provided on the light emitting elements to emit light of the first color, the second color, and the third color. However, the color, type (or kind), and/or number of pixels PXL constituting each pixel unit PXU is not particularly limited. For example, the color of light emitted by each pixel PXL may be variously suitably changed.

The pixel PXL may include at least one light source driven by a set or predetermined control signal (for example, a scan signal and a data signal) and/or a set or predetermined power source (for example, a first power source and a second power source). In one or more embodiments, the light source may include at least one light emitting element LD according to any one of the embodiments of FIGS. 1 and 2, for example, an ultra-small columnar light emitting element LD having a size as small as a nano-meter scale to a micro-meter scale. However, the present disclosure is not necessarily limited thereto, and one or more suitable light emitting elements LD may be used as the light source of the pixel PXL.

In one or more embodiments, each pixel PXL may be configured as an active pixel. However, the types (or kinds), structures, and/or driving methods of the pixels PXL applicable to the display device are not particularly limited. For example, each pixel PXL may be configured as a pixel of a passive or active type (or kind) of light emitting display device having various suitable structures and/or driving methods.

FIGS. 4A, 4B, and 4C are circuit diagrams illustrating embodiments of a pixel included in the display device of FIG. 3. For example, FIGS. 4A, 4B, and 4C show embodiments of the pixel PXL that can be applied to an active display device. However, the types (or kinds) of the pixel PXL and the display device are not limited thereto.

According to one or more embodiments, pixels PXL shown in FIGS. 4A, 4B, and 4C may be any one of the first pixel PXL1, the second pixel PXL2, and the third pixel PXL3 provided in the display panel PNL of FIG. 3. The first pixel PXL1, the second pixel PXL2, and the third pixel PXL3 may have substantially the same or similar structure.

Referring to FIG. 4A, the pixel PXL may include a light source unit LSU for generating light having a luminance corresponding to a data signal, and a pixel circuit PXC for driving the light source unit LSU. Also, the pixel PXL may further include a fourth transistor T4 (or a second switching element) and a fifth transistor T5 (or a first switching element).

The light source unit LSU may include at least one light emitting element LD electrically connected between a first power source VDD and a second power source VSS. For example, the light source unit LSU may include a first pixel electrode ELT1 (also referred to as a first electrode or a first alignment electrode), a second pixel electrode ELT2 (also referred to as a second electrode or a second alignment electrode), and a plurality of light emitting elements LD electrically connected in the same direction between the first and second pixel electrodes ELT1 and ELT2. The first pixel electrode ELT1 may be electrically connected to the first power source VDD via a first power source line PL1. Also, the first pixel electrode ELT1 may be electrically connected to a third power source line PL3 (or a first alignment power source line) through the fifth transistor T5. The second pixel electrode ELT2 may be electrically connected to the second power source VSS through the fourth transistor T4 and a second power source line PL2 (or a second alignment power source line). In one or more embodiments, the first pixel electrode ELT1 may be an anode electrode, and the second pixel electrode ELT2 may be a cathode electrode.

Each of the light emitting elements LD may include a first end (for example, a p-type end) electrically connected to the first power source VDD through the first pixel electrode ELT1 and a second end (for example, an n-type end) electrically connected to the second power source VSS through the second pixel electrode ELT2. For example, the light emitting elements LD may be connected in parallel in a forward direction between the first and second pixel electrodes ELT1 and ELT2. Each of the light emitting elements LD connected in the forward direction between the first power source VDD and the second power source VSS may constitute an effective light source, and these effective light sources may constitute the light source unit LSU of the pixel PXL.

The first power source VDD and the second power source VSS may have different potentials so that the light emitting elements LD can emit light. For example, the first power source VDD may be set as a high potential power source, and the second power source VSS may be set as a low potential power source. In this case, a potential difference between the first power source VDD and the second power source VSS may be set to be equal to or greater than a threshold voltage of the light emitting elements LD during an emission period of the pixel PXL.

First ends of the light emitting elements LD constituting each light source unit LSU may be commonly connected to the pixel circuit PXC through one electrode of the light source unit LSU (for example, the first pixel electrode ELT1 of each pixel PXL), and may be electrically connected to the first power source VDD through the pixel circuit PXC and the first power source line PL1. Second ends of the light emitting elements LD may be commonly connected to the second power source VSS through the other electrode of the light source unit LSU (for example, the second pixel electrode ELT2 of each pixel PXL), the fourth transistor T4, and the second power source line PL2.

The light emitting elements LD may emit light with a luminance corresponding to a driving current supplied through a corresponding pixel circuit PXC. For example, during each frame period, the pixel circuit PXC may supply the driving current corresponding to a grayscale value to be expressed in a corresponding frame to the light source unit LSU. The driving current supplied to the light source unit LSU may be divided and flowed through the light emitting elements LD connected in the forward direction. Accordingly, each light emitting element LD may emit light with a luminance corresponding to a current flowing therethrough, and the light source unit LSU may emit light having a luminance corresponding to the driving current.

For example, luminous efficiency of the light emitting elements LD may vary according to a current. When the number of light emitting elements LD included in the light source unit LSU is different for each pixel PXL, the current flowing through each of the light emitting elements LD with respect to the same driving current may be different for each pixel PXL, and a deviation in luminance may occur for each pixel PXL. For example, when the number of light emitting elements LD included in the light source unit LSU is uniform (or substantially uniform), the deviation in luminance may be alleviated or reduced.

The fourth transistor T4 may be electrically connected between the second pixel electrode ELT2 and the second power source line PL2. For example, a first electrode of the fourth transistor T4 may be electrically connected to the second pixel electrode ELT2, and a second electrode of the fourth transistor T4 may be electrically connected to the second power source line PL2. A gate electrode of the fourth transistor T4 may be connected to a second switching control line. The fourth transistor T4 may electrically connect or separate the second pixel electrode ELT2 and the second power source line PL2 in response to a second switching control signal C_SW2 applied to the second switching control line.

The fifth transistor T5 may be electrically connected between the first pixel electrode ELT1 and the third power source line PL3. For example, a first electrode of the fifth transistor T5 may be electrically connected to the first pixel electrode ELT1, and a second electrode of the fifth transistor T5 may be electrically connected to the third power source line PL3. A gate electrode of the fifth transistor T5 may be connected to a first switching control line. The fifth transistor T5 may electrically connect or separate the first pixel electrode ELT1 and the third power source line PL3 in response to a first switching control signal C_SW1 applied to the first switching control line.

As will be described in more detail herein below with reference to FIG. 7A, in a process of supplying the light emitting elements LD to the display panel PNL, the fourth transistor T4 and the fifth transistor T5 may be turned on, and charges may be supplied to the first and second pixel electrodes ELT1 and ELT2 from the second and third power source lines PL2 and PL3. In addition, as will be described in more detail herein below with reference to FIG. 7D, in a process of aligning the light emitting elements LD, the fourth transistor T4 and the fifth transistor T5 may be turned on, and an electric field may be formed between the first and second pixel electrodes ELT1 and ELT2. After the display device is manufactured, the fifth transistor T5 may be maintained in a turned-off state. After the display device is manufactured, the fourth transistor T4 may be maintained in a turned-on state, but the present disclosure is not limited thereto.

Although one or more embodiments in which the fourth transistor T4 and the fifth transistor T5 receive the first and second switching control signals C_SW1 and C_SW2 have been described, the present disclosure is not limited thereto. For example, the fourth transistor T4 and the fifth transistor T5 may be connected (e.g., electrically coupled) to the same switching control line and may receive the same switching control signal.

The pixel circuit PXC may be electrically connected between the first power source VDD and the first pixel electrode ELT1. The pixel circuit PXC may be electrically connected to a scan line Si and a data line Dj of a corresponding pixel PXL. For example, assuming that the pixel PXL is provided on an i-th horizontal line (row) and a j-th vertical line (column) of the display area DA, the pixel circuit PXC of the pixel PXL may be electrically connected to an i-th scan line Si and a j-th data line Dj of the display area DA, where i and j may be natural numbers.

According to one or more embodiments, the pixel circuit PXC may include a plurality of transistors and at least one capacitor. For example, the pixel circuit PXC may include a first transistor T1, a second transistor T2, and a storage capacitor Cst.

The first transistor T1 may be electrically connected between the first power source VDD and the light source unit LSU. For example, a first electrode (for example, a source electrode) of the first transistor T1 may be electrically connected to the first power source VDD, and a second electrode (for example, a drain electrode) of the first transistor T1 may be electrically connected to the first pixel electrode ELT1. A gate electrode of the first transistor T1 may be electrically connected to a first node N1. The first transistor T1 may control the driving current supplied to the light source unit LSU in response to a voltage of the first node N1. For example, the first transistor T1 may be a driving transistor that controls the driving current of the pixel PXL.

The second transistor T2 may be electrically connected between the data line Dj and the first node N1. For example, a first electrode (for example, a source electrode) of the second transistor T2 may be electrically connected to the data line Dj, and a second electrode (for example, a drain electrode) of the second transistor T2 may be electrically connected to the first node N1. A gate electrode of the second transistor T2 may be electrically connected to the scan line Si. The second transistor T2 may be turned on when a scan signal SSi of a gate-on voltage (for example, a low level voltage) is supplied from the scan line Si to electrically connect the data line Dj and the first node N1.

For each frame period, a data signal DSj of a corresponding frame may be supplied to the data line Dj. The data signal DSj may be transferred to the first node N1 through the second transistor T2 turned on during a period in which the scan signal SSi of the gate-on voltage is supplied. For example, the second transistor T2 may be a switching transistor for transferring each data signal DSj to inside of the pixel PXL.

One electrode of the storage capacitor Cst may be electrically connected to the first power source VDD, and the other electrode of the storage capacitor Cst may be electrically connected to the first node N1. The storage capacitor Cst may charge a voltage corresponding to the data signal DSj supplied to the first node N1 during each frame period.

In FIG. 4A, the transistors included in the pixel circuit PXC, for example, the first, second, fourth, and fifth transistors T1, T2, T4, and T5 are shown as p-type transistors. However, the present disclosure is not necessarily limited thereto, and at least one of the first, second, fourth, and fifth transistors T1, T2, T4, and T5 may be changed to an n-type transistor. In one or more embodiments, the pixel circuit PXC may be configured as a pixel circuit having various suitable structures and/or driving methods.

Referring to FIG. 4B, the pixel circuit PXC may be further connected to a sensing control line SCLi and a sensing line SLj. For example, the pixel circuit PXC of the pixel PXL provided on the i-th horizontal line and the j-th vertical line of the display area DA may be electrically connected to an i-th sensing control line (for example, SCLi) and a j-th sensing line (for example, SLj) of the display area DA. The pixel circuit PXC may further include a third transistor T3. In one or more other embodiments, the sensing line SLj may not be provided, and characteristics of the pixel PXL may be detected by detecting a sensing signal SENj through the data line Dj of a corresponding pixel PXL (or an adjacent pixel).

The third transistor T3 may be electrically connected between the first transistor T1 and the sensing line SLj. For example, one electrode of the third transistor T3 may be connected to one electrode (for example, the source electrode) of the first transistor T1 electrically connected to the first pixel electrode ELT1, and the other electrode of the third transistor T3 may be electrically connected to the sensing line SLj. When the sensing line SLj is not provided, the other electrode of the third transistor T3 may be electrically connected to the data line Dj.

A gate electrode of the third transistor T3 may be connected to the sensing control line SCLi. When the sensing control line SCLi is not provided, the gate electrode of the third transistor T3 may be connected to the scan line Si. The third transistor T3 may be turned on by the sensing control signal SCSi of a gate-on voltage (for example, a high level voltage) supplied to the sensing control line SCLi for a set or predetermined sensing period to electrically connect the sensing line SLj and the first transistor T1.

According to one or more embodiments, a sensing period may be a period for extracting characteristics (for example, a threshold voltage of the first transistor T1 and/or the like) of each of the pixels PXL provided in the display area DA. During the sensing period, the first transistor T1 may be turned on by supplying a set or predetermined reference voltage capable of turning on the first transistor T1 to the first node N1 through the data line Dj and the second transistor T2, or by connecting each pixel PXL to a current source and/or the like. In one or more embodiments, the first transistor T1 may be electrically connected to the sensing line SLj by supplying the sensing control signal SCSi of the gate-on voltage to the third transistor T3 to turn on the third transistor T3. Thereafter, the sensing signal SENj may be obtained through the sensing line SLj, and the characteristics of each pixel PXL including the threshold voltage of the first transistor T1 and/or the like may be detected using the sensing signal SENj. Information on the characteristics of each pixel PXL may be used to convert image data so that a deviation in characteristics between the pixels PXL provided in the display area DA can be compensated or reduced.

Although FIG. 4B shows embodiments in which all of the first to fifth transistors T1 to T5 are n-type transistors, the present disclosure is not necessarily limited thereto. For example, at least one of the first to fifth transistors T1 to T5 may be changed to a p-type transistor.

According to one or more embodiments, when the pixel circuit PXC (or the pixel PXL) includes the third transistor T3, the fifth transistor T5 may not be provided. For example, in a process of manufacturing the display device, the sensing line SLj may be used as the third power source line PL3, and the third transistor T3 may perform a function of the fifth transistor T5.

Although one or more embodiments in which effective light sources constituting each light source unit LSU, for example, the light emitting elements LD, are connected in parallel is shown in FIGS. 4A, 4B, and 4C, the present disclosure is not necessarily limited thereto. For example, the light source unit LSU of each pixel PXL may be configured to include a series structure. For example, the pixel PXL may include two or more light source units LSU, and the two or more light source units LSU may be connected in series between the pixel circuit PXC and the fourth transistor T4.

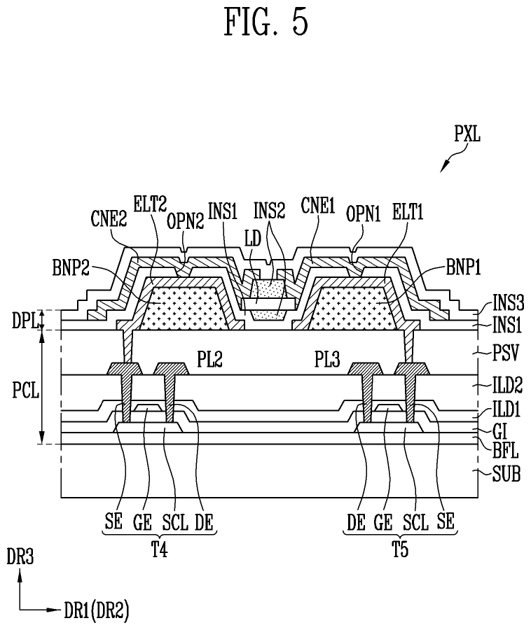

FIG. 5 is a cross-sectional view illustrating one or more embodiments of the pixel included in the display device of FIG. 3.

In FIG. 5, as an example, each electrode is shown as a single-layer electrode and each insulating layer is shown as a single-layer insulating layer to simplify the illustration of one pixel PXL, but the present disclosure is not limited thereto.

In the present disclosure, the term “connection” between two components may include both an electrical connection and a physical connection.

Referring to FIGS. 1 to 5, the pixel PXL may include a pixel circuit layer PCL and a display element layer DPL (or a light emitting element layer) provided on the substrate SUB.

For convenience, the pixel circuit layer PCL will be described first, and then the display element layer DPL will be described.

The pixel circuit layer PCL may include a buffer layer BFL, a transistor, and a passivation layer PSV. As an example of the transistor, the fourth transistor T4 and the fifth transistor T5 (or the third transistor T3) are shown in FIG. 5. The configuration of each of the first to third transistors T1 to T3 shown in FIGS. 4A to 4C may be the same as that of the fourth transistor T4 and/or the fifth transistor T5.

The buffer layer BFL may be provided and/or formed on the substrate SUB, and may prevent or reduce the diffusion of impurities into the transistor. The buffer layer BFL may be an inorganic insulating layer including an inorganic material. The buffer layer BFL may include at least one of silicon nitride (SiNx), silicon oxide (SiOx), silicon oxynitride (SiOxNy), or a metal oxide such as aluminum oxide (AlOx). The buffer layer BFL may be provided as a single layer, but may be provided as a multilayer of at least a double layer. When the buffer layer BFL is provided as a multilayer, each layer may be formed of the same material or may be formed of different materials. The buffer layer BFL may not be provided, depending on the material of the substrate SUB, process conditions, and the like.

The fourth transistor T4 and the fifth transistor T5 may be transistors for supplying charges to the first and second pixel electrodes ELT1 and ELT2, or for forming an electric field in the first and second pixel electrodes ELT1 and ELT2.

Each of the fourth transistor T4 and the fifth transistor T5 may include a semiconductor pattern SCL, a gate electrode GE, a first electrode SE (or a first transistor electrode), and a second electrode DE (or a second transistor electrode). The first electrode SE may be any one of a source electrode or a drain electrode, and the second electrode DE may be the other electrode. For example, when the first electrode SE is a source electrode, the second electrode DE may be a drain electrode.

The semiconductor pattern SCL may be provided and/or formed on the buffer layer BFL. The semiconductor pattern SCL may include a first contact region in contact with the first electrode SE and a second contact region in contact with the second electrode DE. A region between the first contact region and the second contact region may be a channel region. This channel region may overlap the gate electrode GE of a corresponding transistor. The semiconductor pattern SCL may be a semiconductor pattern made of amorphous silicon, polysilicon, low temperature polysilicon, an oxide semiconductor, an organic semiconductor, and/or the like. The channel region may be, for example, a semiconductor pattern that is not doped with impurities, and may be an intrinsic semiconductor. The first contact region and the second contact region may be semiconductor patterns doped with impurities.

The gate electrode GE may be provided and/or formed on a gate insulating layer GI to correspond to the channel region of the semiconductor pattern SCL. The gate electrode GE may be provided on the gate insulating layer GI to overlap the channel region of the semiconductor pattern SCL. The gate electrode GE may be a single layer formed of one selected from a group consisting of copper (Cu), molybdenum (Mo), tungsten (W), aluminum neodymium (AlNd), titanium (Ti), aluminum (Al), silver (Ag), alloys thereof, and mixtures thereof. In one or more embodiments, the gate electrode GE may be a double or multilayer formed of a low-resistance material such as molybdenum (Mo), titanium (Ti), copper (Cu), aluminum (Al), and/or silver (Ag), to reduce wiring resistance.

The gate insulating layer GI may be an inorganic insulating layer including an inorganic material. For example, the gate insulating layer GI may include at least one of silicon nitride (SiNx), silicon oxide (SiOx), silicon oxynitride (SiOxNy), or a metal oxide such as aluminum oxide (AlOx). However, the material of the gate insulating layer GI is not limited to the above-described embodiments. According to some embodiments, various suitable materials for which the gate insulating layer GI may have insulating properties may be applied. For example, the gate insulating layer GI may be formed of an organic insulating layer including an organic material. The gate insulating layer GI may be provided as a single layer, or may be provided as a multilayer of at least a double layer.

The first electrode SE and the second electrode DE may be provided and/or formed on a second interlayer insulating layer ILD2, and may be in connect with the first contact region and the second contact region of the semiconductor pattern SCL through contact holes sequentially penetrating the gate insulating layer GI, a first interlayer insulating layer ILD1, and the second interlayer insulating layer ILD2. For example, the first electrode SE may be in contact with the first contact region of the semiconductor pattern SCL, and the second electrode DE may be in contact with the second contact region of the semiconductor pattern SCL. Each of the first and second electrodes SE and DE may include the same material as the gate electrode GE, or may include one or more materials selected from materials exemplified as materials constituting the gate electrode GE.

The first interlayer insulating layer ILD1 may include the same material as the gate insulating layer GI, or may include one or more materials selected from materials exemplified as materials constituting the gate insulating layer GI.

The second interlayer insulating layer ILD2 may be provided and/or formed on the first interlayer insulating layer ILD1. The second interlayer insulating layer ILD2 may be an inorganic insulating layer including an inorganic material or an organic insulating layer including an organic material. According to one or more embodiments, the second interlayer insulating layer ILD2 may include the same material as the first interlayer insulating layer ILD1, but the present disclosure is not limited thereto. The second interlayer insulating layer ILD2 may be provided as a single layer, or may be provided as a multilayer of at least a double layer. According to one or more embodiments, the second interlayer insulating layer ILD2 may not be provided.

In the above-described embodiments, the first and second electrodes SE and DE of the transistor have been described as separate electrodes electrically connected to the semiconductor pattern SCL through the contact holes sequentially penetrating the gate insulating layer GI, the first interlayer insulating layer ILD1, and the second interlayer insulating layer ILD2, but the present disclosure is not limited thereto. According to one or more embodiments, the first electrode SE of the transistor may be the first contact region adjacent to the channel region of the semiconductor pattern SCL, and the second electrode DE of the transistor may be the second contact region adjacent to the channel region of the semiconductor pattern SCL.

The transistor may be configured as a low temperature polysilicon thin film transistor (LTPS TFT), but the present disclosure is not limited thereto. According to one or more embodiments, the transistor may be formed of an oxide semiconductor thin film transistor. In the above-described embodiments, a case in which the transistor is a thin film transistor having a top gate structure has been described as an example, but the present disclosure is not limited thereto. A structure of the transistor may be variously suitably changed. For example, the transistor may be a thin film transistor having a bottom gate structure.

The pixel circuit layer PCL may further include the storage capacitor Cst described with reference to FIG. 4A, a driving voltage line for providing a driving voltage to the transistor (or the pixel PXL), and/or the like.

In one or more embodiments, the pixel circuit layer PCL may further include the second power source line PL2 and the third power source line PL3. The second power source line PL2 may be connected to the second electrode DE of the fourth transistor T4, and the third power source line PL3 may be connected to the second electrode DE of the fifth transistor T5.

The passivation layer PSV may be provided and/or formed on the transistor.

The passivation layer PSV may be provided in a form including an organic insulating layer, an inorganic insulating layer, or an organic insulating layer provided on the inorganic insulating layer. The inorganic insulating layer may include, for example, at least one of silicon oxide (SiOx), silicon nitride (SiNx), silicon oxynitride (SiOxNy), or a metal oxide such as aluminum oxide (AlOx). The organic insulating layer may include, for example, at least one of an acrylic resin (e.g., polyacrylates resin), an epoxy resin, a phenolic resin, a polyamide resin, a polyimide resin, an unsaturated polyester resin, a poly-phenylene ether resin, a poly-phenylene sulfide resin, or a benzocyclobutene resin.

The display element layer DPL may be provided on the passivation layer PSV.

The display element layer DPL may include first and second bank patterns BNP1 and BNP2, the first and second pixel electrodes ELT1 and ELT2, the light emitting element LD, and first and second contact electrodes CNE1 and CNE2. Also, the display element layer DPL may include first, second, and third insulating layers INS1, INS2, and INS3.

The first and second bank patterns BNP1 and BNP2 may be positioned in an emission area EMA (refer to FIG. 3) and may be spaced apart from each other. The first and second bank patterns BNP1 and BNP2 may be support members for supporting the first and second pixel electrodes ELT1 and ELT2 in order to change surface profiles (or shapes) of the first and second pixel electrodes ELT1 and ELT2 in a third direction DR3 so that light emitted from the light emitting elements LD is guided in an image display direction (for example, a front direction) of the display device. For example, the first and second bank patterns BNP1 and BNP2 may change the surface profiles (or shapes) of the first and second pixel electrodes ELT1 and ELT2 in the third direction DR3.

The first and second bank patterns BNP1 and BNP2 may be provided and/or formed between the passivation layer PSV and a corresponding electrode in the emission area of a corresponding pixel PXL. For example, the first bank pattern BNP1 may be provided and/or formed between the passivation layer PSV and the first pixel electrode ELT1, and the second bank pattern BNP2 may be provided and/or formed between the passivation layer PSV and the second pixel electrode ELT2.

The first and second bank patterns BNP1 and BNP2 may be an inorganic insulating layer including an inorganic material or an organic insulating layer including an organic material. According to one or more embodiments, the first and second bank patterns BNP1 and BNP2 may include a single organic insulating layer and/or a single inorganic insulating layer, but the present disclosure is not limited thereto. According to one or more embodiments, the first and second bank patterns BNP1 and BNP2 may be provided as a multilayer in which at least one organic insulating layer and at least one inorganic insulating layer are stacked. However, materials of the first and second bank patterns BNP1 and BNP2 are not limited to the above-described embodiments. According to one or more embodiments, the first bank pattern BNP1 may include a conductive material.

The first and second bank patterns BNP1 and BNP2 may have a cross-section of a trapezoidal shape in which a width becomes narrower from one surface (for example, an upper surface) of the passivation layer PSV toward an upper side in the third direction DR3, but the present disclosure is not limited thereto. According to one or more embodiments, the first and second bank patterns BNP1 and BNP2 may include a curved surface having a cross-section of a semi-elliptical shape, a semi-circular shape (or a semi-spherical shape), and/or the like, in which a width becomes narrower from one surface of the passivation layer PSV toward an upper side in the third direction DR3. When viewed in cross-section, shapes of the first and second bank patterns BNP1 and BNP2 are not limited to the above-described embodiments, and may be variously suitably changed within a range capable of improving the efficiency of light emitted from each of the light emitting elements LD. The first and second bank patterns BNP1 and BNP2 adjacent in the first direction DR1 may be provided on the same surface of the passivation layer PSV, and may have the same height (or thickness) in the third direction DR3.

In the above-described embodiments, a case in which the first and second bank patterns BNP1 and BNP2 are provided and/or formed on the passivation layer PSV, and the first and second bank patterns BNP1 and BNP2 and the passivation layer PSV are formed by different processes has been described as an example, but the present disclosure is not limited thereto. According to one or more embodiments, the first and second bank patterns BNP1 and BNP2 and the passivation layer PSV may be formed by the same process. In this case, the first and second bank patterns BNP1 and BNP2 may be partial regions of the passivation layer PSV.

The first and second pixel electrodes ELT1 and ELT2 may be provided and/or formed on corresponding first and second bank patterns BNP1 and BNP2.

The first and second pixel electrodes ELT1 and ELT2 may each independently be formed of a material having a constant (or a substantially constant) reflectance so that light emitted from the light emitting element LD is guided in the image display direction of the display device. The first and second pixel electrodes ELT1 and ELT2 may each independently be formed of a conductive material having a constant (or a substantially constant) reflectance. The conductive material may include an opaque metal so that light emitted from the light emitting element LD can be effectively or suitably reflected in the image display direction of the display device. The opaque metal may include, for example, a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and/or alloys thereof. According to one or more embodiments, the first and second pixel electrodes ELT1 and ELT2 may each independently include a transparent conductive material. The transparent conductive material may include a conductive oxide such as indium tin oxide (ITO), indium zinc oxide (IZO), zinc oxide (ZnOx), indium gallium zinc oxide (IGZO), and/or indium tin zinc oxide (ITZO), a conductive polymer such as poly(3,4-ethylenedioxythiophene) (PEDOT), and/or the like.

When each of the first and second pixel electrodes ELT1 and ELT2 includes a transparent conductive material, a separate conductive layer made of an opaque metal may be added to reflect light emitted from the light emitting element LD in the image display direction of the display device. However, the material of each of the first and second pixel electrodes ELT1 and ELT2 is not limited to the above-described materials.

The first and second pixel electrodes ELT1 and ELT2 may each independently be provided and/or formed of a single layer, but the present disclosure is not limited thereto. According to one or more embodiments, the first and second pixel electrodes ELT1 and ELT2 may each independently be provided and/or formed as a multilayer in which at least two or more of metals, alloys, conductive oxides, or conductive polymers are stacked. The first and second pixel electrodes ELT1 and ELT2 may each independently be formed of a multilayer including at least a double layer so as to minimize or reduce the distortion due to signal delay when transmitting a signal (or voltage) to the both ends of the light emitting elements LD. For example, The first and second pixel electrodes ELT1 and ELT2 may each independently be formed of a multilayer sequentially stacked in the order of indium tin oxide (ITO)/silver (Ag)/indium tin oxide (ITO).

According to one or more embodiments, the first pixel electrode ELT1 may be electrically connected to the fifth transistor T5 (for example, the first electrode SE of the fifth transistor T5) through a first contact hole penetrating the passivation layer PSV, and the second pixel electrode ELT2 may be electrically connected to the fourth transistor T4 (for example, the first electrode SE of the fourth transistor T4) through a second contact hole penetrating the passivation layer PSV.

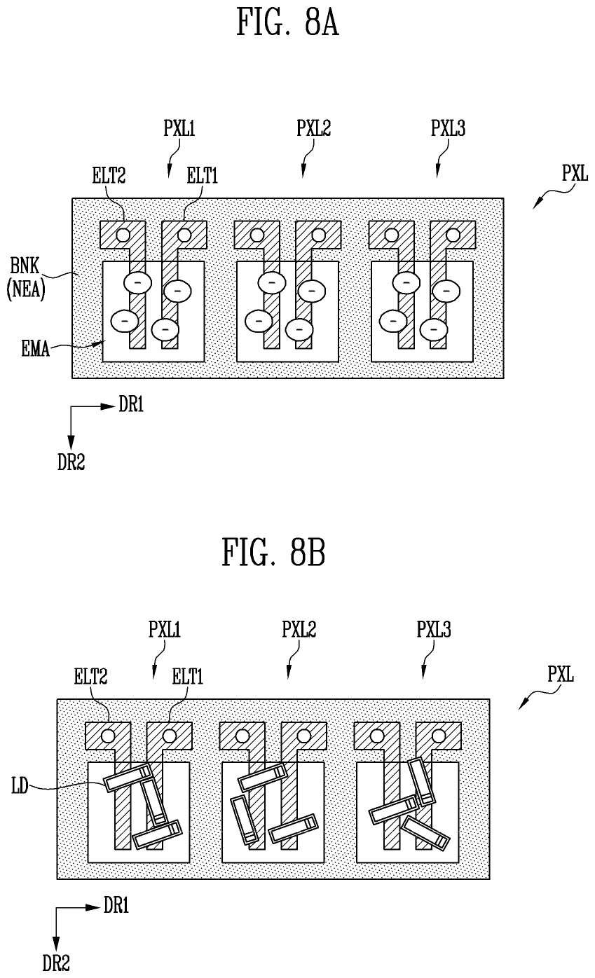

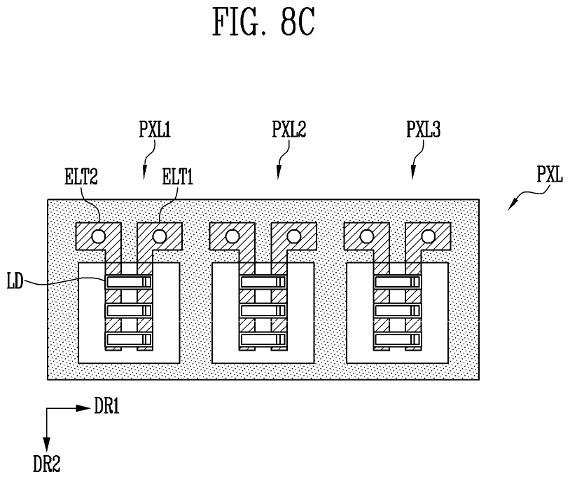

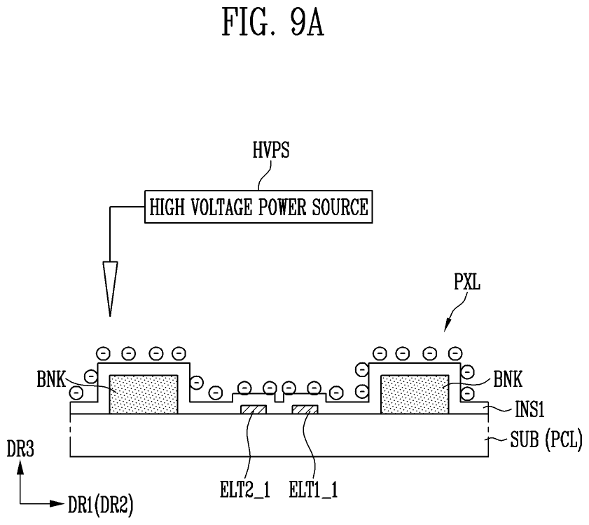

The first pixel electrode ELT1 and the second pixel electrode ELT2 may receive charges from the second and third power source lines PL2 and PL3, respectively, and may be used as a charging unit for supplying or transferring the light emitting elements LD. The first pixel electrode ELT1 and the second pixel electrode ELT2 may be independently arranged for each pixel PXL so that electrostatic charges may be uniformly (or substantially uniformly) supplied to the pixels PXL (refer to FIGS. 8A to 8C).

In one or more embodiments, the first pixel electrode ELT1 and the second pixel electrode ELT2 may receive a set or predetermined alignment signal (or an alignment voltage) from the second and third power source lines PL2 and PL3, and may be used as an alignment electrode (or an alignment line) for aligning the light emitting elements LD. For example, the first pixel electrode ELT1 may receive a first alignment signal (or a first alignment voltage, for example, a ground voltage) from the third power source line PL3 and may be used as a first alignment electrode (or a first alignment line). The second pixel electrode ELT2 may receive a second alignment signal (or a second alignment voltage, for example, an AC voltage) from the second power source line PL2 and may be used as a second alignment electrode (or a second alignment line).

After the light emitting elements LD are aligned, the first pixel electrode ELT1 and the second pixel electrode ELT2 may be used as driving electrodes for driving the light emitting elements LD.

The light emitting element LD may be an ultra-small light emitting diode using a material of an inorganic crystalline structure, and having a size as small as, for example, a nano-meter scale to a micro-meter scale. For example, the light emitting element LD may include a first semiconductor layer, a second semiconductor layer, an active layer, and an insulating film. The first semiconductor layer may include a semiconductor layer having a set or predetermined type (e.g., a set or predetermined dopant), and the second semiconductor layer may include a semiconductor layer of a different type (e.g., different dopant) from that of the first semiconductor layer. For example, the first semiconductor layer may include an N-type semiconductor layer, and the second semiconductor layer may include a P-type semiconductor layer. The first semiconductor layer and the second semiconductor layer may include at least one semiconductor material of InAlGaN, GaN, AlGaN, InGaN, AlN, or InN. The active layer may be positioned between the first semiconductor layer and the second semiconductor layer, and may have a single or multiple quantum well structure. When an electric field equal to or greater than a set or predetermined voltage is applied to the both ends of the light emitting element LD, electron-hole pairs may be combined in the active layer, and light may be emitted.

At least two to several tens of light emitting elements LD may be arranged and/or provided in the emission area EMA. However, the number of light emitting elements LD arranged and/or provided in the emission area EMA is not limited thereto. According to one or more embodiments, the number of light emitting elements LD arranged and/or provided in the emission area EMA may be variously suitably changed.

Each of the light emitting elements LD may emit any one of color light and/or white light. In one or more embodiments, each of the light emitting elements LD may emit blue light in a short wavelength band, but the present disclosure is not limited thereto.

The first insulating layer INS1 (or a second insulator) may be provided and/or formed on the first and second pixel electrodes ELT1 and ELT2.

The first insulating layer INS1 may include an inorganic insulating layer made of an inorganic material or an organic insulating layer made of an organic material. The first insulating layer INS1 may be formed of an inorganic insulating layer advantageous for protecting the light emitting element LD from the pixel circuit layer PCL of the pixel PXL. For example, the first insulating layer INS1 may include at least one of silicon nitride (SiNx), silicon oxide (SiOx), silicon oxynitride (SiOxNy), or a metal oxide such as aluminum oxide (AlOx), but the present disclosure is not limited thereto. According to one or more embodiments, the first insulating layer INS1 may be formed of an organic insulating layer advantageous for planarizing supporting surfaces of the light emitting elements LD.

The first insulating layer INS1 may include a first opening OPN1 exposing one area of the first pixel electrode ELT1 and a second opening OPN2 exposing one area of the second pixel electrode ELT2. The first insulating layer INS1 may cover the remaining area except for the exposed areas of the first and second pixel electrodes ELT1 and ELT2 (for example, areas corresponding to the first and second openings OPN1 and OPN2). The light emitting elements LD may be provided (or aligned) on the first insulating layer INS1 between the first pixel electrode ELT1 and the second pixel electrode ELT2.

The second insulating layer INS2 (or an insulating pattern) may be provided and/or formed on the light emitting element LD. The second insulating layer INS2 may be provided and/or formed on the light emitting element LD to partially cover an outer peripheral surface of the light emitting element LD. The active layer of the light emitting element LD may not come into contact with an external conductive material by (e.g., due to) the second insulating layer INS2. The second insulating layer INS2 may cover only a portion of the outer peripheral surface of the light emitting element LD to expose the both ends of the light emitting element LD to outside. The second insulating layer INS2 may be formed as an independent insulating pattern (e.g., an insulating pattern not connected to other insulating patterns) in the pixel PXL, but the present disclosure is not limited thereto.

The second insulating layer INS2 may be formed of a single layer or a multilayer, and may include an inorganic insulating layer including at least one inorganic material or an organic insulating layer including at least one organic material. According to design conditions of a display device to which the light emitting element LD is applied, the second insulating layer INS2 may be formed of an inorganic insulating layer including an inorganic material or an organic insulating layer including an organic material. After the light emitting element LD is aligned in the pixel PXL, the second insulating layer INS2 may be formed on the light emitting element LD to prevent or reduce the separation of the light emitting element LD from the aligned position.

The first contact electrode CNE1 may be provided on the first pixel electrode ELT1 to contact or be connected to the first pixel electrode ELT1 through the first opening OPN1 of the first insulating layer INS1. According to one or more embodiments, when a capping layer is provided on the first pixel electrode ELT1, the first contact electrode CNE1 may be provided on the capping layer and connected to the first pixel electrode ELT1 through the capping layer. The above-described capping layer may protect the first pixel electrode ELT1 from (or reduce the occurrence of) defects occurring during a manufacturing process of the display device, and may further strengthen the adhesive force between the first pixel electrode ELT1 and the pixel circuit layer PCL positioned thereunder. The capping layer may include a transparent conductive material such as indium zinc oxide (IZO).

In one or more embodiments, the first contact electrode CNE1 may be provided and/or formed on the first end of the light emitting element LD to be connected to the first end of the light emitting element LD. Accordingly, the first pixel electrode ELT1 and the first end of the light emitting element LD may be electrically connected to each other through the first contact electrode CNE1. For example, the second insulating film EB of the light emitting element LD may be removed by the solution SOL shown in FIGS. 7C and 7D, or the second insulating film EB of the light emitting element LD that is not covered by the second insulating layer INS2 may be removed during an etching process for forming the second insulating layer INS2. For example, at least a portion of the second insulating film EB of the light emitting element LD may be removed, and the first and second ends EP1 and EP2 (refer to FIG. 2) of the light emitting element LD (e.g., the first and second semiconductor layers 11 and 13, refer to FIG. 2) may be exposed. The first contact electrode CNE1 may contact one of the first and second semiconductor layers 11 and 13 (for example, the first semiconductor layer 11) of the light emitting element LD.

Similar to the first contact electrode CNE1, the second contact electrode CNE2 may be provided on the second pixel electrode ELT2 to contact or be connected to the second pixel electrode ELT2 through the second opening OPN2 of the first insulating layer INS1. According to one or more embodiments, when the capping layer is provided on the second pixel electrode ELT2, the second contact electrode CNE2 may be provided on the capping layer and connected to the second pixel electrode ELT2 through the capping layer. In some embodiments, the second contact electrode CNE2 may be provided and/or formed on the second end of the light emitting element LD to be connected to the second end of the light emitting element LD. Accordingly, the second pixel electrode ELT2 and the second end of the light emitting element LD may be electrically connected to each other through the second contact electrode CNE2.

The first and second contact electrodes CNE1 and CNE2 may be formed of one or more suitable transparent conductive materials so that light emitted from the light emitting element LD and reflected by the first and second pixel electrodes ELT1 and ELT2 is guided in the image display direction of the display device without loss. For example, the first and second contact electrodes CNE1 and CNE2 may include at least one of various suitable transparent conductive materials such as indium tin oxide (ITO), indium zinc oxide (IZO), zinc oxide (ZnOx), indium gallium zinc oxide (IGZO), and/or indium tin zinc oxide (ITZO), and may be configured to be substantially transparent or translucent to satisfy a set or predetermined light transmittance. For example, the first and second contact electrodes CNE1 and CNE2 may be substantially transparent to have a transmittance of about 80% or more, or about 90% or more.

However, materials of the first and second contact electrodes CNE1 and CNE2 are not limited to the above-described embodiments. According to one or more embodiments, the first and second contact electrodes CNE1 and CNE2 may be made of one or more suitable opaque conductive materials. The first and second contact electrodes CNE1 and CNE2 may be formed of a single layer or a multilayer.

The shapes of the first and second contact electrodes CNE1 and CNE2 are not limited to a set or specific shape, and may be variously suitably changed so long as the first and second contact electrodes CNE1 and CNE2 may be electrically stably (or suitably) connected to the light emitting element LD. The shapes of the first and second contact electrodes CNE1 and CNE2 may also be variously suitably changed in consideration of a connection relationship with electrodes provided thereunder.

The first and second contact electrodes CNE1 and CNE2 may be provided to be spaced apart from each other in the first direction DR1. For example, the first contact electrode CNE1 and the second contact electrode CNE2 may be provided to be spaced apart from each other with a set or predetermined distance therebetween on the second insulating layer INS2. The first contact electrode CNE1 and the second contact electrode CNE2 may be provided on the same layer and formed by the same process. However, the present disclosure is not limited thereto. According to one or more embodiments, the first and second contact electrodes CNE1 and CNE2 may be provided on different layers and formed by different processes.

The third insulating layer INS3 may be provided and/or formed on the first and second contact electrodes CNE1 and CNE2. The third insulating layer INS3 may be an inorganic insulating layer including an inorganic material or an organic insulating layer including an organic material. For example, the third insulating layer INS3 may have a structure in which at least one inorganic insulating layer or at least one organic insulating layer is alternately stacked. The third insulating layer INS3 may cover the entire display element layer DPL to prevent or reduce the flow of moisture from the outside into the display element layer DPL including the light emitting elements LD.

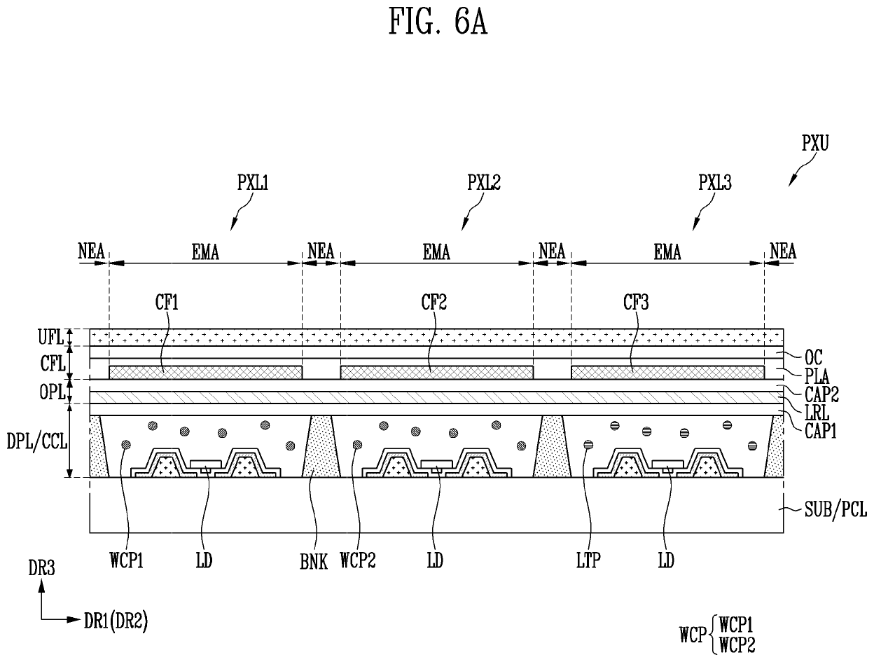

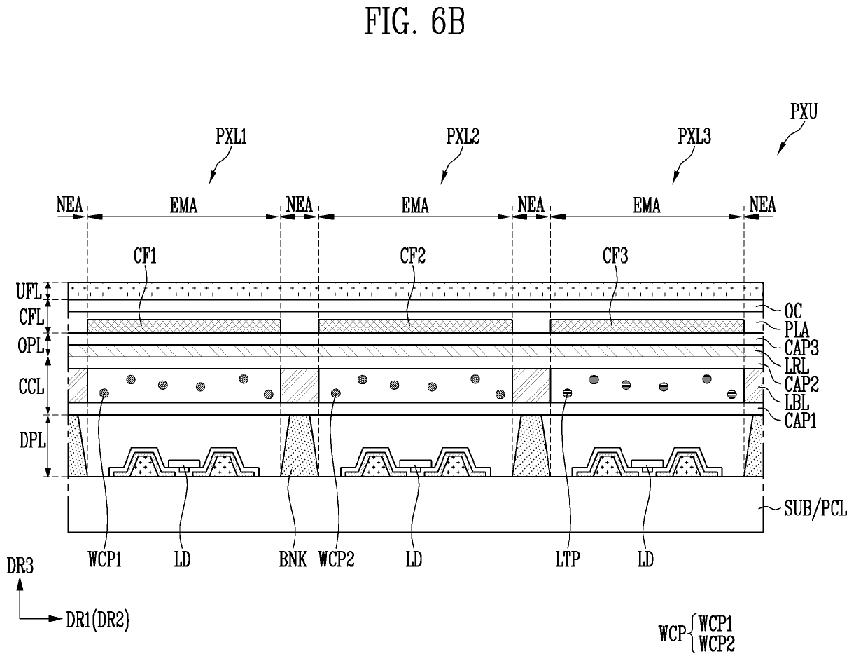

FIGS. 6A and 6B are cross-sectional views illustrating embodiments of a pixel unit included in the display device of FIG. 3. For convenience of description, individual components of the pixel circuit layer PCL and the display element layer DPL are schematically shown in FIGS. 6A and 6B.

First, referring to FIGS. 3, 5, and 6A, light emitting elements LD provided in the first pixel PXL1, the second pixel PXL2, and the third pixel PXL3 may emit light of the same color. For example, the first pixel PXL1, the second pixel PXL2, and the third pixel PXL3 may include light emitting elements LD that emit light of the third color, for example, blue light. A color conversion unit CCL and/or a color filter unit CFL may be provided to the first pixel PXL1, the second pixel PXL2, and the third pixel PXL3 to display a full-color image. However, the present disclosure is not limited thereto, and the first pixel PXL1, the second pixel PXL2, and the third pixel PXL3 may include light emitting elements LD emitting (e.g., configured to emit) light of different colors.

The color conversion unit CCL may be provided on the same layer as the display element layer DPL. For example, the color conversion unit CCL may be provided between banks BNK.

Each bank BNK may be positioned in a non-emission area NEA. The bank BNK may be a structure defining (or partitioning) the emission area EMA into the first to third pixels PXL1, PXL2, and PXL3. In one or more embodiments, the bank BNK may be a pixel defining layer or a dam structure defining an area to which the light emitting elements LD are to be supplied in a process of supplying the light emitting elements LD to the first to third pixels PXL1, PXL2, and PXL3. For example, as the emission area EMA is partitioned into each of the first to third pixels PXL1, PXL2, and PXL3 by the bank BNK, a desired (or suitable) amount and/or type (or kind) of light emitting elements and/or solution may be supplied to the emission area EMA.

The color conversion unit CCL may include a wavelength conversion pattern WCP (or color conversion particles), a light transmission pattern LTP, and a first capping layer CAP1. According to an example, the wavelength conversion pattern WCP may include a first wavelength conversion pattern WCP1 and a second wavelength conversion pattern WCP2.

The first wavelength conversion pattern WCP1 may be provided to overlap the emission area EMA of the first pixel PXL1. For example, the first wavelength conversion pattern WCP1 may be provided between the banks BNK to overlap the emission area EMA of the first pixel PXL1 when viewed on a plane (e.g., in a plan view).

The second wavelength conversion pattern WCP2 may be provided to overlap the emission area EMA of the second pixel PXL2. For example, the second wavelength conversion pattern WCP2 may be provided between the banks BNK to overlap the emission area EMA of the second pixel PXL2 when viewed on a plane (e.g., in a plan view).

The light transmission pattern LTP may be provided to overlap the emission area EMA of the third pixel PXL3. For example, the light transmission pattern LTP may be provided between the banks BNK to overlap the emission area EMA of the third pixel PXL3 when viewed on a plane (e.g., in a plan view).

In one or more embodiments, the first wavelength conversion pattern WCP1 may include first color conversion particles that convert light of the third color emitted from the light emitting element LD into light of the first color. For example, when the light emitting element LD is a blue light emitting element emitting blue light and the first pixel PXL1 is a red pixel, the first wavelength conversion pattern WCP1 may include first quantum dots that convert blue light emitted from the blue light emitting element into red light.

For example, the first wavelength conversion pattern WCP1 may include a plurality of first quantum dots dispersed in a set or predetermined matrix material such as a base resin. The first quantum dots may absorb blue light and shift a wavelength according to an energy transition to emit red light. When the first pixel PXL1 is a pixel of a different color, the first wavelength conversion pattern WCP1 may include first quantum dots corresponding to the color of the first pixel PXL1.

In one or more embodiments, the second wavelength conversion pattern WCP2 may include second color conversion particles that convert light of the third color emitted from the light emitting element LD into light of the second color. For example, when the light emitting element LD is a blue light emitting element emitting blue light and the second pixel PXL2 is a green pixel, the second wavelength conversion pattern WCP2 may include second quantum dots that convert blue light emitted from the blue light emitting element into green light.

For example, the second wavelength conversion pattern WCP2 may include a plurality of second quantum dots dispersed in a set or predetermined matrix material such as a base resin. The second quantum dots may absorb blue light and shift a wavelength according to an energy transition to emit green light. When the second pixel PXL2 is a pixel of a different color, the second wavelength conversion pattern WCP2 may include second quantum dots corresponding to the color of the second pixel PXL2.

In one or more embodiments, the first quantum dots and the second quantum dots may have shapes such as spherical, pyramidal, multi-arm, and/or cubic nanoparticles, nanotubes, nanowires, nanofibers, nanoplatelet particles, and/or the like, but the present disclosure is not necessarily limited thereto. The shapes of the first quantum dots and the second quantum dots may be variously suitably changed.

In one or more embodiments, absorption coefficients of the first quantum dots and the second quantum dots may be increased by injecting blue light having a relatively short wavelength in the visible light region to the first quantum dots and the second quantum dots, respectively. Accordingly, the efficiency of light finally emitted from the first pixel PXL1 and the second pixel PXL2 may be increased, and excellent or improved color reproducibility may be secured. In addition, the manufacturing efficiency of the display device may be improved by configuring the pixel units of the first to third pixels PXL1, PXL2, and PXL3 using light emitting elements LD of the same color (for example, blue light emitting elements).

In one or more embodiments, the light transmission pattern LTP may be provided to efficiently or suitably use (or utilize) the light of the third color emitted from the light emitting element LD. For example, when the light emitting element LD is a blue light emitting element emitting blue light and the third pixel PXL3 is a blue pixel, the light transmission pattern LTP may include at least one type (or kind) of light scattering particles in order to efficiently or suitably use (or utilize) the light emitted from the light emitting element LD.

For example, the light transmission pattern LTP may include a plurality of light scattering particles dispersed in a set or predetermined matrix material such as a base resin. For example, the light transmission pattern LTP may include light scattering particles such as silica, but the material constituting the light scattering particles is not limited thereto.

The light scattering particles do not have to be provided only in the emission area EMA of the third pixel PXL3. For example, the light scattering particles may be selectively included in the first and/or second wavelength conversion patterns WCP1 and WCP2.

The first capping layer CAP1 may seal (or cover) the wavelength conversion pattern WCP and the light transmission pattern LTP. The first capping layer CAP1 may be provided between a low refractive index layer LRL and the display element layer DPL. The first capping layer CAP1 may be provided over the first to third pixels PXL1, PXL2, and PXL3. The first capping layer CAP1 may prevent or reduce the penetration of impurities such as moisture and/or air from outside that may damage and/or contaminate the color conversion unit CCL.

In one or more embodiments, the first capping layer CAP1 may be formed of a single layer or a multilayer including at least one insulating material of silicon oxide (SiOx), silicon nitride (SiNx), silicon oxynitride (SiOxNy), aluminum oxide (AlOx), or titanium oxide (TiOx), but the present disclosure is not necessarily limited thereto. According to one or more embodiments, the first capping layer CAP1 may not be provided.

An optical layer OPL may include the low refractive index layer LRL and a second capping layer CAP2. The optical layer OPL may be provided on the color conversion unit CCL. The optical layer OPL may be provided on the display element layer DPL.

The low refractive index layer LRL may be provided between the first capping layer CAP1 and the second capping layer CAP2. The low refractive index layer LRL may be provided between the color conversion unit CCL and the color filter unit CFL. The low refractive index layer LRL may be provided over the first to third pixels PXL1, PXL2, and PXL3.

The low refractive index layer LRL may serve to improve light efficiency by recycling the light provided from the color conversion unit CCL by total reflection. For example, the low refractive index layer LRL may have a relatively lower refractive index compared to the color conversion unit CCL.

In one or more embodiments, the low refractive index layer LRL may include a base resin and hollow particles dispersed in the base resin. The hollow particles may include hollow silica particles. In some embodiments, the hollow particles may be pores formed by porogen, but are not necessarily limited thereto. In one or more embodiments, the low refractive index layer LRL may include at least one of zinc oxide (ZnO) particles, titanium dioxide (TiO₂) particles, or nano silicate particles, but the present disclosure is not limited thereto.

The second capping layer CAP2 may be provided on the low refractive index layer LRL. The second capping layer CAP2 may be provided between the color filter unit CFL and the low refractive index layer LRL. The second capping layer CAP2 may be provided over the first to third pixels PXL1, PXL2, and PXL3. The second capping layer CAP2 may prevent or reduce the penetration of impurities such as moisture and/or air from outside that may damage and/or contaminate the low refractive index layer LRL.

In one or more embodiments, the second capping layer CAP2 may be formed of a single layer or a multilayer including at least one insulating material of silicon oxide (SiOx), silicon nitride (SiNx), silicon oxynitride (SiOxNy), aluminum oxide (AlOx), or titanium oxide (TiOx), but the present disclosure is not necessarily limited thereto.

The color filter unit CFL may be provided on the second capping layer CAP2. The color filter unit CFL may be provided over the first to third pixels PXL1, PXL2, and PXL3. The color filter unit CFL may include color filters CF1, CF2, and CF3, a planarization layer PLA, and an overcoat layer OC.

In one or more embodiments, the color filters CF1, CF2, and CF3 may be provided on the second capping layer CAP2. The color filters CF1, CF2, and CF3 may overlap emission areas EMA of the first to third pixels PXL1, PXL2, and PXL3, respectively, when viewed on a plane (e.g., in a plan view).

In one or more embodiments, a first color filter CF1 may transmit light of the first color, but may not transmit light of the second color and light of the third color. For example, the first color filter CF1 may include a colorant related to the first color.

In one or more embodiments, a second color filter CF2 may transmit the light of the second color, but may not transmit the light of the first color and the light of the third color. For example, the second color filter CF2 may include a colorant related to the second color.

In one or more embodiments, a third color filter CF3 may transmit the light of the third color, but may not transmit the light of the first color and the light of the second color. For example, the third color filter CF3 may include a colorant related to the third color.

In one or more embodiments, the planarization layer PLA may be provided on the color filters CF1, CF2, and CF3. The planarization layer PLA may cover the color filters CF1, CF2, and CF3. The planarization layer PLA may cancel or reduce a step difference caused by the color filters CF1, CF2, and CF3. The planarization layer PLA may be provided over the first to third pixels PXL1, PXL2, and PXL3.

According to one or more embodiments, the planarization layer PLA may include an organic material such as an acrylate resin, an epoxy resin, a phenolic resin, a polyamide resin, a polyimide resin, a polyester resin, a polyphenylenesulfide resin, and/or benzocyclobutene (BCB). However, the present disclosure is not necessarily limited thereto, and the planarization layer PLA may include one or more suitable inorganic materials including silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and/or titanium oxide (TiOx).

The overcoat layer OC may be provided on the planarization layer PLA. The overcoat layer OC may be provided between an upper film layer UFL and the color filter unit CFL. The overcoat layer OC may be provided over the first to third pixels PXL1, PXL2, and PXL3. The overcoat layer OC may cover lower members including the color filter unit CFL. The overcoat layer OC may prevent or reduce the penetration of moisture and/or air into the above-described lower members. In addition, the overcoat layer OC may protect the above-described lower members from foreign substances such as dust.

In one or more embodiments, the overcoat layer OC may include an organic material such as an acrylate resin, an epoxy resin, a phenolic resin, a polyamide resin, a polyimide resin, a polyester resin, a polyphenylenesulfide resin, and/or benzocyclobutene (BCB). However, the present disclosure is not necessarily limited thereto, and the overcoat layer OC may include one or more suitable inorganic materials including silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and/or titanium oxide (TiOx).

The upper film layer UFL may be provided on the color filter unit CFL. The upper film layer UFL may be provided on the outside of the display device DD to reduce external influence on the display device DD. The upper film layer UFL may be provided over the first to third pixels PXL1, PXL2, and PXL3.

In one or more embodiments, the upper film layer UFL may include an anti-reflective (AR) coating layer. The AR coating layer may refer to a configuration in which a material having an anti-reflection function is coated on one surface of a set or specific configuration or structure. Here, the material to be coated may have a low reflectance. According to an example, the material used as the AR coating layer may include any one of silicon oxide (SiOx), silicon nitride (SiNx), aluminum oxide (AlOx), or titanium oxide (TiOx). However, the present disclosure is not limited thereto, and one or more suitable materials may be applied.

Although one or more embodiments in which the color conversion unit CCL is provided on (e.g., as part of) the same layer as the display element layer DPL have been described in FIG. 6A, the present disclosure is not limited thereto.

Referring to FIG. 6B, the color conversion unit CCL may be provided on the display element layer DPL. For example, the first capping layer CAP1 may seal (or cover) an area in which the light emitting elements LD are provided, and the color conversion unit CCL may be provided on the first capping layer CAP1.

In one or more embodiments, the color conversion unit CCL may further include a light blocking layer LBL (or a light blocking pattern). The light blocking layer LBL may be provided on the display element layer DPL. The light blocking layer LBL may be provided between the first capping layer CAP1 and the second capping layer CAP2. The light blocking layer LBL may be provided to surround the first wavelength conversion pattern WCP1, the second wavelength conversion pattern WCP2, and the light transmission pattern LTP at the boundaries between the first to third pixels PXL1, PXL2, and PXL3.

The light blocking layer LBL may define the emission area EMA and the non-emission area NEA of the pixel PXL. For example, the light blocking layer LBL may not overlap the emission area EMA when viewed on a plane (e.g., in a plan view). The light blocking layer LBL may overlap the non-emission area NEA when viewed on a plane (e.g., in a plan view). According to an example, an area in which the light blocking layer LBL is not provided may be defined as the emission area EMA of the first to third pixels PXL1, PXL2, and PXL3.

In one or more embodiments, the light blocking layer LBL may be formed of an organic material including at least one of graphite, carbon black, black pigment, or black dye. In one or more other embodiments, the light blocking layer LBL may be formed of a metal material including chromium (Cr), but is not limited as long as it is a material capable of blocking, absorbing, or reducing light.

The second capping layer CAP2 may seal (or cover) the first wavelength conversion pattern WCP1, the second wavelength conversion pattern WCP2, and the light transmission pattern LTP.

The low refractive index layer LRL may be provided between the second capping layer CAP2 and a third capping layer CAP3. Like the first capping layer CAP1 and the second capping layer CAP2, the third capping layer CAP3 may be formed of a single layer or a multilayer including at least one insulating material of silicon oxide (SiOx), silicon nitride (SiNx), silicon oxynitride (SiOxNy), aluminum oxide (AlOx), and/or titanium oxide (TiOx), but the present disclosure is not limited thereto.

FIGS. 7A, 7B, 7C, and 7D are cross-sectional views schematically illustrating a method of manufacturing a display device according to embodiments. FIGS. 8A to 8C are plan views schematically illustrating a method of manufacturing a display device according to embodiments. FIGS. 8A to 8C show a state before a light emitting element LD is supplied, a state in which the light emitting element LD is supplied, and a state in which the light emitting element LD is aligned based on the pixel unit PXU of FIG. 3.

First, referring to FIGS. 3 to 7A and 8A to 8C, a panel including a first pixel electrode ELT1 and a second pixel electrode ELT2 may be prepared.

The first pixel electrode ELT1, the second pixel electrode ELT2, and a bank BNK may be provided or formed on a pixel circuit layer PCL (or a substrate SUB). A first insulating layer INS1 may be provided or formed to cover the first pixel electrode ELT1, the second pixel electrode ELT2, and the bank BNK. As shown in FIGS. 8A to 8C, the bank BNK may define an emission area EMA and may partially overlap the first pixel electrode ELT1 and the second pixel electrode ELT2.

The first pixel electrode ELT1 and the second pixel electrode ELT2 may be spaced apart from each other in the emission area EMA. Also, the first and second pixel electrodes ELT1 and ELT2 may be separately provided for each pixel PXL (or for each emission area EMA). As shown in FIGS. 8A to 8C, the first and second pixel electrodes ELT1 and ELT2 of a first pixel PXL1 may be separated from the first and second pixel electrodes ELT1 and ELT2 of a second pixel PXL2, respectively, and the first and second pixel electrodes ELT1 and ELT2 of the second pixel PXL2 may be separated from the first and second pixel electrodes ELT1 and ELT2 of a third pixel PXL3, respectively.

The pixel circuit layer PCL may include a fourth transistor T4 and a fifth transistor T5 (or a third transistor T3, refer to FIG. 4C).

The first pixel electrode ELT1 may be electrically connected to a third power source line PL3 (or a first alignment power source line) through the fifth transistor T5 (or a first switching element), and the second pixel electrode ELT2 may be electrically connected to a second power source line PL2 (or a second alignment power source line) through the fourth transistor T4 (or a second switching element).

Thereafter, a first voltage may be applied to at least one of the first pixel electrode ELT1 and the second pixel electrode ELT2. For example, the first voltage may be applied to the first pixel electrode ELT1 and the second pixel electrode ELT2, respectively.

For example, the first voltage may be applied to the second power source line PL2 and the third power source line PL3. When the fifth transistor T5 is turned on using a switching control signal C_SW (or a first switching control signal C_SW1, refer to FIG. 4A), the first pixel electrode ELT1 may be connected to the third power source line PL3, and charges may be supplied to the first pixel electrode ELT1 through the third power source line PL3. Similarly, when the fourth transistor T4 is turned on using a switching control signal C_SW (or a second switching control signal C_SW2, refer to FIG. 4A), the second pixel electrode ELT2 may be connected to the second power source line PL2, and charges may be supplied to the second pixel electrode ELT2 through the second power source line PL2. A portion of the first insulating layer INS1 in contact with the first and second pixel electrodes ELT1 and ETL2 may be charged by the charges. For example, a portion of the first insulating layer INS1 may be charged with a negative polarity.

Thereafter, the fourth and fifth transistors T4 and T5 may be turned off using a switching control signal C_SW. The first pixel electrode ELT1 and the second pixel electrode ELT2 may be in a floating state, and may have previously supplied charges. As shown in FIG. 8A, because the first and second pixel electrodes ELT1 and ELT2 are separated for each pixel PXL, electrostatic charges may be uniformly (or substantially uniformly) applied and maintained to each pixel PXL.

For example, when the first pixel electrode ELT1 (and/or the second pixel electrode ELT2) is commonly connected to the first to third pixels PXL1, PXL2, and PXL3, a change in the amount of charge in the first pixel electrode ELT1 of at least one of the first to third pixels PXL1, PXL2, and PXL3 may affect the remaining first pixel electrodes ELT1 of the first to third pixels PXL1, PXL2, and PXL3. For example, in a process of supplying the light emitting element LD to the first pixel PXL1, a change in the amount of charge in the first pixel electrode ELT1 of the first pixel PXL1 may affect the first pixel electrodes ELT1 of the second and third pixels PXL2 and PXL3, and a desired amount of light emitting elements LD may not be supplied to the second and third pixels PXL2 and PXL3. Accordingly, in order to uniformly (or substantially uniformly) apply and maintain the electrostatic charges for each pixel PXL, the first and second pixel electrodes ELT1 and ELT2 may be separated from each other for each pixel PXL, and the fourth and fifth transistors T4 and T5 may be maintained in a turned-off state after the charges are supplied to the first and second pixel electrodes ELT1 and ELT2.

Thereafter, as shown in FIG. 7B, the charged light emitting elements LD may be attached to the first and second pixel electrodes ELT1 and ELT2 using static electricity between the charged light emitting elements LD and the first insulating layer INS1. For example, as shown in FIG. 8B, the light emitting elements LD may be attached to the emission area EMA of the panel.

In one or more embodiments, the light emitting elements LD may be charged and attached to an outer peripheral surface of a transfer roller ROL, and the light emitting elements LD may be attached to or transferred to the panel (or the emission area EMA) using the transfer roller ROL. For example, the light emitting elements LD shown in FIG. 2 may be charged with a positive polarity using a separate charging unit (for example, arc charging), and the light emitting elements LD may be fixed to the outer peripheral surface of the transfer roller ROL having negative electricity. When the transfer roller ROL rotates and moves in a first direction DR1 (or a second direction DR2) on the panel, the light emitting elements LD may be transferred only to the emission area EMA by electrostatic force (or electrostatic attraction) of the charged first insulating layer INS1. The transfer roller ROL may be non-contact with the panel (e.g.. may not be in contact with the panel). For example, the light emitting elements LD may be transferred to the panel from the transfer roller ROL in a non-contact manner.

The number of light emitting elements LD attached to the emission area EMA of the pixel PXL may be proportional to the amount of charge (or static electricity) applied to the first and second pixel electrodes ELT1 and ELT2 of the pixel PXL. Because the first and second pixel electrodes ELT1 and ELT2 are separated from each other for each pixel PXL, the electrostatic charges may be uniformly (or substantially uniformly) applied and maintained for each pixel PXL. Accordingly, a uniform (or substantially uniform) number of light emitting elements LD may be supplied to each pixel PXL. In one or more embodiments, because the fourth and fifth transistors T4 and T5 are turned off before supplying the light emitting elements LD so that the first and second pixel electrodes ELT1 and ELT2 are separated from each other for each pixel PXL, in a process of supplying the light emitting elements LD, a change in the amount of charge in a set or specific pixel may not affect other pixels, and a uniform (or substantially uniform) number of light emitting elements LD may be supplied to each pixel PXL according to the amount of charge uniformly (or substantially uniformly) applied and maintained for each pixel PXL.

Thereafter, as shown in FIG. 7C, a solution SOL (or a solvent) may be supplied or applied to the pixel PXL. For example, the solution SOL may be supplied only to the emission area EMA (e.g., the emission area EMA defined by the bank BNK) of the pixel PXL by an inkjet method. The light emitting elements LD may flow in the pixel PXL by (e.g., in) the solution SOL. The bank BNK may prevent or reduce the flow of the solution SOL (and the light emitting elements LD flowing in the solution SOL) in a pixel PXL into the emission area of another adjacent pixel.

In one or more embodiments, the solution SOL may be volatile and may include a material capable of dissolving the second insulating film EB of the light emitting element LD. For example, the solution SOL may include a solvent capable of dissolving carbon, acrylates resin, and/or polymer. However, the solution SOL is not limited thereto.

Thereafter, as shown in FIG. 7D, an alignment voltage may be applied between the first and second pixel electrodes ELT1 and ELT2. For example, a first alignment voltage may be applied to the first pixel electrode ELT1, and a second alignment voltage may be applied to the second pixel electrode ELT2. One of the first and second alignment voltages may be an AC voltage, and the other of the first and second alignment voltages may be a ground voltage.

For example, the ground voltage may be applied to the third power source line PL3, and the third power source line PL3 and the first pixel electrode ELT1 may be electrically connected to each other through the fifth transistor T5. The AC voltage may be applied to the second power source line PL2, and the second power source line PL2 and the second pixel electrode ELT2 may be electrically connected to each other through the fourth transistor T4. In this case, as an electric field is formed between the first and second pixel electrodes ELT1 and ELT2, the light emitting elements LD may be self-aligned between the first and second pixel electrodes ELT1 and ELT2 as shown in FIGS. 7D and 8C.

By volatilizing the solution SOL, or removing the solution SOL by other suitable methods, after the light emitting elements LD are aligned, the light emitting elements LD may be stably or suitably arranged between the first and second pixel electrodes ELT1 and ELT2.

Thereafter, as shown in FIG. 5, a second insulating layer INS2 (or an insulating pattern) may be formed on the light emitting element LD, and the light emitting element LD may be fixed (e.g., affixed). Thereafter, by forming a first contact electrode CNE1 and a second contact electrode CNE2 on a first end and a second end of the light emitting element LD, the light emitting element LD may be connected between the first and second pixel electrodes ELT1 and ELT2.

As described above, the electrostatic charges may be uniformly (or substantially uniformly) applied to each pixel PXL using the first and second pixel electrodes ELT1 and ELT2 independently arranged for each pixel PXL, and a uniform (or substantially uniform) number of light emitting elements LD may be supplied to each pixel PX using the electrostatic force caused by the electrostatic charges (e.g., through an electrostatic printing method). Because the number of light emitting elements LD is uniform (or substantially uniform) for each pixel PXL, a deviation in luminance between the pixels PXL may be alleviated or reduced.

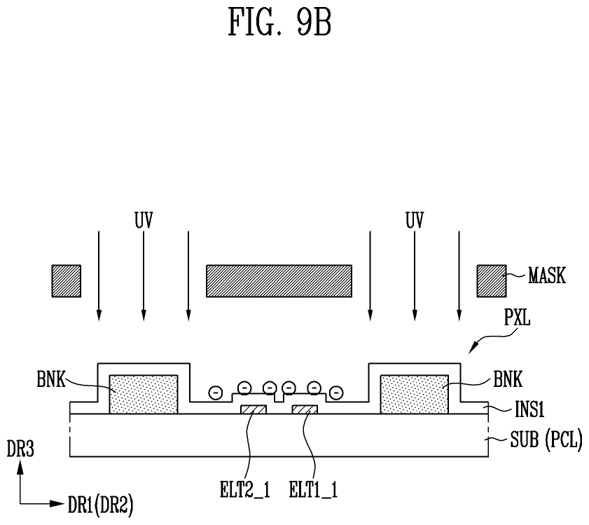

FIGS. 9A and 9B are cross-sectional views schematically illustrating a method of manufacturing a display device according to one or more embodiments.

Referring to FIGS. 3 to 8C, 9A, and 9B, a method of supplying electrostatic charges of FIGS. 9A and 9B may be used instead of the method of supplying the electrostatic charges of FIG. 7A.

As shown in FIG. 9A, the first insulating layer INS1 may be completely charged using a high voltage power source HVPS generating a high voltage (for example, 10 KV). For example, the first insulating layer INS1 may be charged with negative charges by directly supplying charges generated using the high voltage power source HVPS to the first insulating layer INS1.

In one or more embodiments, in a process of charging the first insulating layer INS1 using the high voltage power source HVPS, elements of the pixel circuit layer PCL may be damaged. Accordingly, the pixel circuit layer PCL may further include elements for preventing or reducing static electricity to protect the other elements thereof. For example, only when an element (e.g., an element damaged by static electricity) is not provided in the pixel circuit layer PCL (e.g., only when the elements of the pixel circuit layer PCL are not damaged by static electricity), the first insulating layer INS1 may be charged using the high voltage power source HVPS.

Thereafter, as shown in FIG. 9B, the static electricity may be partially removed from the non-emission area NEA by irradiating light to the bank BNK, for example, the non-emission area NEA defined by the bank BNK (refer to FIGS. 8A to 8C). For example, only the non-emission area NEA may be exposed by a mask MASK, and ultraviolet light UV may be irradiated to the exposed non-emission area NEA, so that the static electricity may be removed from the non-emission area NEA.

Thereafter, as described with reference to FIGS. 7B to 7D, the charged light emitting elements LD may be attached to or transferred to the pixel PXL (or panel) by the static electricity. The solution SOL may be supplied to the pixel PXL, and the alignment voltage may be applied between the first and second pixel electrodes ELT1 and ELT2, so that the light emitting element LD may be self-aligned between the first and second pixel electrodes ELT1 and ELT2.

As described above, the static electricity may be removed from the non-emission area NEA of the pixel PXL by completely charging the first insulating layer INS1 using the high voltage power source HVPS and irradiating light.

According to the method of manufacturing a display device according to the embodiments of the present disclosure, the electrostatic charges may be uniformly (or substantially uniformly) applied to each pixel using the first and second pixel electrodes independently arranged for each pixel, and a uniform (or substantially uniform) number of light emitting elements may be supplied to each pixel using the electrostatic force caused by the electrostatic charges.

Because the display device includes a uniform (or substantially uniform) number of light emitting elements for each pixel, the deviation in luminance may be alleviated or reduced.

The effects according to the embodiments of the present disclosure are not limited by the contents described above, and more various effects are included in the disclosure.

The embodiments of the present disclosure have been described above with reference to the accompanying drawings. However, those skilled in the art or those of ordinary skill in the art to which the present disclosure pertains will appreciate that various modifications and changes can be made to the present disclosure without departing from the spirit and technical scope of the present disclosure described in the following claims.

Therefore, the technical protection scope of the present disclosure is not limited to the content described in the detailed description of the specification, but should be defined by the appended claims and their equivalents.

What is claimed is:

1. A method of manufacturing a display device comprising:
forming an insulating layer on a panel comprising a first electrode and a second electrode in each of emission areas and spaced apart from each other;
applying a first voltage to at least one of the first electrode and the second electrode; and
attaching charged light emitting elements to the emission areas utilizing static electricity between the light emitting elements and the insulating layer.

2. The method of claim 1, wherein each of the light emitting elements has a diameter or length in a range of a nano-meter scale to a micro-meter scale.

3. The method of claim 1, wherein each of the light emitting elements comprises:
a first semiconductor layer;
a second semiconductor layer;
an active layer between the first semiconductor layer and the second semiconductor layer;
an insulating film around an outer peripheral surface of the active layer; and
an insulator around the first semiconductor layer, the second semiconductor layer, and the insulating film.

4. The method of claim 3, wherein the insulator comprises at least one of carbon or an acrylic resin.

5. The method of claim 3, wherein the insulator covers the first and second semiconductor layers exposed by the insulating film.

6. The method of claim 1, wherein the attaching the charged light emitting elements to the emission areas comprises:
charging the light emitting elements and attaching the charged light emitting elements to an outer peripheral surface of a transfer roller; and
transferring the charged light emitting elements to the emission areas from the transfer roller.

7. The method of claim 1, wherein the applying the first voltage to at least one of the first electrode and the second electrode comprises:
applying the first voltage to each of the first electrode and the second electrode.

8. The method of claim 1, wherein the first electrode is configured to be separated for each of the emission areas, and is connected to a first alignment power source line through a first switching element, and
wherein the second electrode is configured to be separated for each of the emission areas, and is connected to a second alignment power source line through a second switching element.

9. The method of claim 8, wherein the applying the first voltage to at least one of the first electrode and the second electrode comprises:
connecting the first electrode and the second electrode to the first alignment power source line and the second alignment power source line by turning on the first switching element and the second switching element, respectively; and
turning off the first switching element and the second switching element before attaching the light emitting elements to the emission areas.

10. The method of claim 1, further comprising:
supplying a solvent to the emission areas; and
aligning the light emitting elements between the first electrode and the second electrode in each of the emission areas by applying a first alignment voltage and a second alignment voltage to the first electrode and the second electrode, respectively,
wherein one of the first alignment voltage and the second alignment voltage is an AC voltage, and another of the first alignment voltage and the second alignment voltage is a ground voltage.

11. The method of claim 10, wherein the supplying the solvent to the emission areas comprises:
supplying the solvent to each of the emission areas through an inkjet method.

12. The method of claim 10, further comprising:
forming an insulating pattern on the light emitting elements between the first electrode and the second electrode.

13. A method of manufacturing a display device, the method comprising:
forming an insulating layer on a panel comprising emission areas and a non-emission area;
charging the insulating layer by applying a first power source to the insulating layer;
partially removing static electricity from the insulating layer in the non-emission area by irradiating light to the non-emission area; and
attaching charged light emitting elements to the emission areas utilizing static electricity between the light emitting elements and the insulating layer.

14. The method of claim 13, wherein the attaching the charged light emitting elements to the emission areas comprises:
charging the light emitting elements and attaching the charged light emitting elements to an outer peripheral surface of a transfer roller; and
attaching the charged light emitting elements to the emission areas from the transfer roller.

15. The method of claim 13, further comprising:
supplying a solvent to the emission areas; and
aligning the light emitting elements between a first electrode and a second electrode in each of the emission areas by applying a first alignment voltage and a second alignment voltage to the first electrode and the second electrode under the insulating layer, respectively,
wherein one of the first alignment voltage and the second alignment voltage is an AC voltage, and another of the first alignment voltage and the second alignment voltage is a ground voltage.

16. A display device comprising:
a first electrode and a second electrode in each of emission areas of a substrate and spaced apart from each other;
an insulating layer on the substrate to cover the first electrode and the second electrode;
a light emitting element on the insulating layer and aligned between the first electrode and the second electrode;
a first contact electrode on the first electrode and in contact with a first end of the light emitting element; and
a second contact electrode on the second electrode and in contact with a second end of the light emitting element,
wherein the light emitting element comprises:
a first semiconductor layer;
a second semiconductor layer;
an active layer between the first semiconductor layer and the second semiconductor layer;
an insulating film around an outer peripheral surface of the active layer; and
an insulator around the first semiconductor layer, the second semiconductor layer, and the insulating film.

17. The display device of claim 16, wherein the insulator comprises at least one of carbon or an acrylic resin.

18. The display device of claim 16, wherein the light emitting element has a diameter or length in a range of a nano-meter scale to a micro-meter scale.

19. The display device of claim 16, wherein the first electrode is configured to be separated for each of the emission areas, and is connected to a first alignment power source line through a first switching element, and
wherein the second electrode is configured to be separated for each of the emission areas, and is connected to a second alignment power source line through a second switching element.

20. The display device of claim 16, further comprising:
color conversion particles on the light emitting element and configured to convert a wavelength of light emitted from the light emitting element.
